(19) United States
(12) Patent Application Publication
(10) Pub. No.: US 2025/0241051 A1
(43) Pub. Date: Jul. 24, 2025

(54) SEMICONDUCTOR STRUCTURE INCLUDING ISOLATION PROTECTION FEATURES AND MANUFACTURING METHOD THEREOF

(71) Applicant: TAIWAN SEMICONDUCTOR MANUFACTURING COMPANY, LTD., Hsinchu (TW)

(72) Inventors: Chun-Yi CHOU, Hsinchu (TW); Guan-Lin CHEN, Hsinchu (TW); Shi-Ning JU, Hsinchu (TW); Kuo-Cheng CHIANG, Hsinchu (TW); Chih-Hao WANG, Hsinchu (TW)

(73) Assignee: TAIWAN SEMICONDUCTOR MANUFACTURING COMPANY, LTD., Hsinchu (TW)

(21) Appl. No.: 18/417,953

(22) Filed: Jan. 19, 2024

(51) Int. Cl. H01L 21/8234; H01L 21/3115; H01L 27/088; H01L 29/06; H01L 29/423; H01L 29/66; H01L 29/775; H01L 29/786

(52) U.S. Cl. CPC H10D 84/038; H01L 21/31155; H10D 30/014; H10D 30/43; H10D 30/6735; H10D 30/6757; H10D 62/121; H10D 64/017; H10D 84/0151; H10D 84/83

(57) ABSTRACT

A method for manufacturing a semiconductor structure includes: forming stacks each including a first nanosheet layer and a second nanosheet layer; forming isolation features among the stacks; performing an ion implantation process such that top portions of the isolation features are formed into isolation protection elements; forming a gate structure, each of the stacks having two portions that are located at two opposite sides of the gate structure; removing the two portions of each of the stacks to form source/drain recesses such that the first nanosheet layer, the second nanosheet layer, and the stacks are respectively formed into a first nanosheet, a second nanosheet, and patterned stacks; forming source/drain portions respectively in the source/drain recesses; removing a dummy gate of the gate structure; removing the second nanosheet of each of the patterned stacks; and forming a gate electrode around the first nanosheet of each of the patterned stacks.

### BACKGROUND

In fabrication of nanosheet transistors, such as gate-all-around (GAA) transistors or forksheet transistors, isolation features are formed to prevent current leakage among different transistors. Enhancement in manufacturing process of the nanosheet transistors are urged to further reduce current leakage and/or improve performance of the transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 25 are schematic views illustrating intermediate stages of the method for manufacturing the semiconductor structure shown in FIG. 1 in accordance with some embodiments.

FIG. 26 is a flow diagram illustrating another method for manufacturing another semiconductor structure in accordance with some embodiments.

FIGS. 27 to 48 are schematic views illustrating intermediate stages of the another method for manufacturing the another semiconductor structure shown in FIG. 26 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “bottommost,” “upper,” “uppermost.” “lower,” “lowermost,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The present disclosure is directed to a manufacturing method of forming isolation units that separate nanosheet transistors, and a semiconductor structure produced thereby. The nanosheet transistors may be gate-all-around (GAA) type of nanosheet transistors, or forksheet type of nanosheet transistors, but are not limited thereto. That is, the semiconductor structure includes the nanosheet transistors, and the isolation units disposed among the nanosheet transistors. Each of the isolation units includes an upper portion and a lower portion. The lower portion serves as an isolation element (e.g., 51B shown in FIGS. 25, 47 or 48), while the upper portion serves as an isolation protection element (e.g., 51A′ shown in FIGS. 25, 47 or 48). For each of the isolation units, the upper portion (the isolation protection element) is formed to have a carbon content greater than that of the lower portion (the isolation element), and can effectively prevent loss of the lower portion during manufacturing process of the nanosheet transistors.

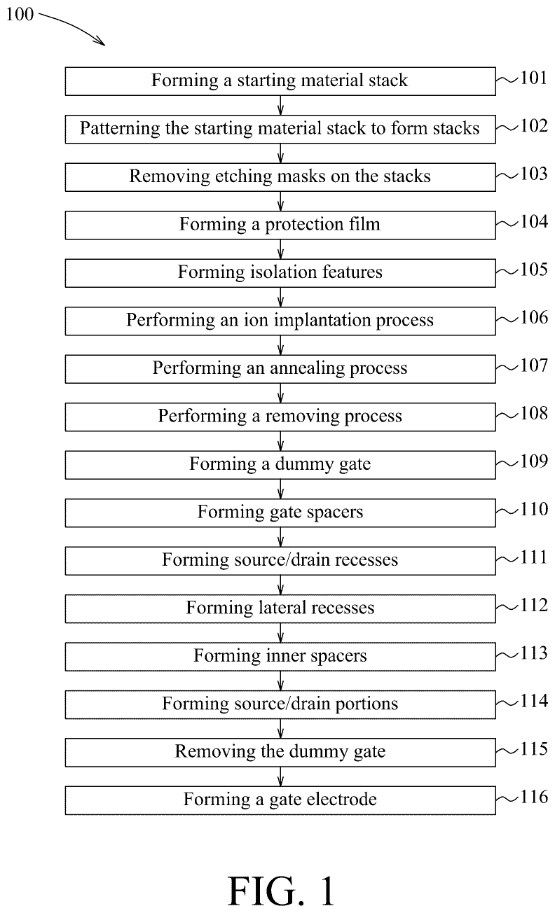

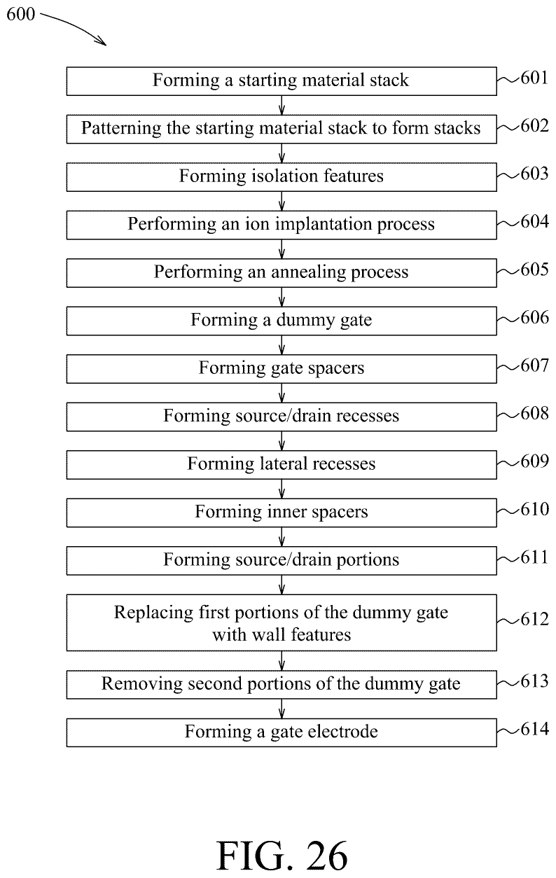

Such isolation units may be formed by: forming isolation features among stacks, performing an ion implantation process to dope carbon and/or silicon into upper portions of the isolation features, followed by an annealing process. The doped upper portions each serves as the isolation protection element, while the undoped lower portions remain unaffected and each serves as the isolation element. Prior to performing the ion implantation process, stack coverings are respectively formed on the stacks to prevent the stacks from being affected in the ion implantation process. Such stack coverings may be removed from, or may remain on the stacks, based on practical needs or product design. The present disclosure provides different embodiments to respectively illustrate two process flows, in which the stack coverings are removed in a first process flow (e.g., a method 100 as shown in FIGS. 1 to 25), and the stack coverings remain in a second process flow (e.g., a method 600 as shown in FIGS. 26 to 48).

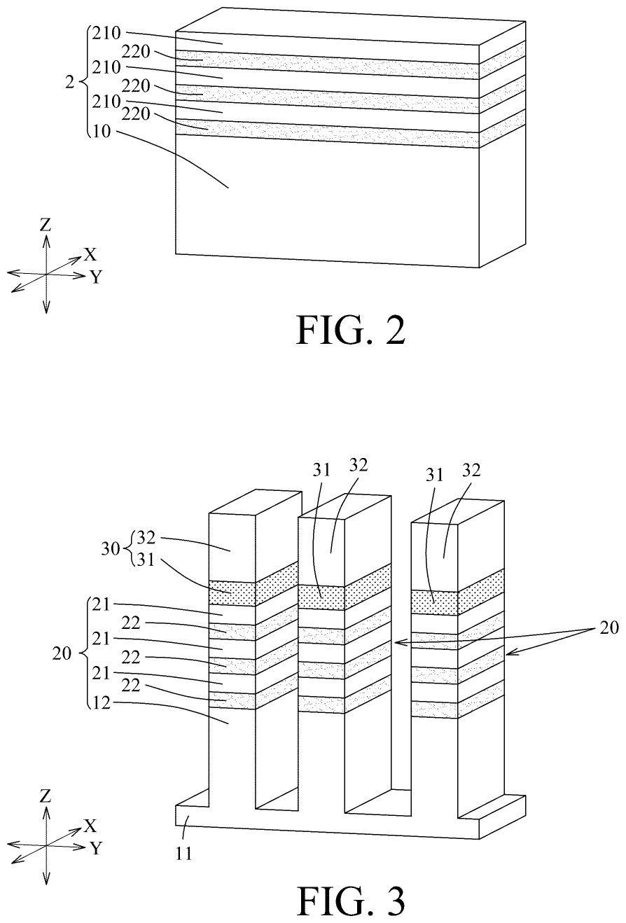

FIGS. 1 to 25 describe a process flow that the stack coverings are removed during the manufacturing process of the semiconductor structure (for example, a semiconductor structure 300 shown in FIG. 25). FIG. 1 is a flow diagram illustrating a method 100 for manufacturing the semiconductor structure 300 in accordance with some embodiments. FIGS. 2 to 25 illustrate schematic views of intermediate stages of the method 100 in accordance with some embodiments. Some repeating structures are omitted in FIGS. 2 to 25 for the sake of brevity. Additional steps can be provided before, after or during the method, and some of the steps described herein may be replaced by other steps or be eliminated.

Referring to FIG. 1 and the example illustrated in FIG. 2, the method 100 begins at step 101, where a starting material stack 2 is formed.

The starting material stacks 2 includes at least one first nanosheet material layer 210 and at least one second nanosheet material layer 220. Numbers of each of the first nanosheet material layer 210 and the second nanosheet material layer 220 may be determined according to practical needs and product design. As shown in FIG. 2, there are three of the first nanosheet material layers 210, and three of the second nanosheet material layers 220. The first and second nanosheet material layers 210, 220 alternate with each other along a Z direction. In some embodiments, the first nanosheet material layers 210 may include silicon, and the second nanosheet material layer 220 may include silicon germanium. Other suitable numbers and/or materials of each of the first and second nanosheet material layers 210, 220 are within the contemplated scope of the present disclosure.

The starting material stack 2 may further include a substrate material layer 10 beneath a bottommost one of the first and second nanosheet material layers 210, 220. In some embodiments, the substrate material layer 10 may be made of elemental semiconductor materials, such as crystalline silicon, diamond, or germanium; compound semiconductor materials, such as silicon carbide, gallium arsenide, indium arsenide, or indium phosphide; or alloy semiconductor materials, such as silicon germanium, silicon germanium carbide, gallium arsenide phosphide, or gallium indium phosphide. The substrate material layer 10 may be doped with p-type impurities or n-type impurities, or undoped. In addition, the substrate material layer 10 may be a bulk silicon substrate, a silicon-on-insulator (SOI) substrate, or a germanium-on-insulator (GOI) substrate. In some embodiments, the substrate material layer 10 may be made of silicon. Other suitable materials for forming substrate material layer 10 are within the contemplated scope of disclosure.

The starting material stack 2 extends along a Y direction that transverse (e.g., perpendicular to) with the Z direction, and along an X direction that transverse (e.g., perpendicular to) with the Z direction and the Y direction.

Referring to FIG. 1 and the example illustrated in FIG. 3, the method 100 proceeds to step 102, where mask units 30 are formed on the starting material stack 2 shown in FIG. 2, and then the starting material stack 2 is patterned into stacks 20. In FIG. 3, it merely illustrates a portion of each of the stacks 20, and in some embodiments, each of the stacks 20 is elongated in the X direction.

In some embodiments, each of the mask units 30 includes one or more layer(s) of masks to facilitate the patterning of the starting material stack 2, and after patterning the starting material stack 2, the mask units 30 are respectively disposed on the stacks 20. For instance, as shown in FIG. 3, patterning masks 31 of the mask units 30 are respectively disposed on the stacks 20, and patterning masks 32 of the mask units 30 are respectively disposed on the patterning masks 31. The patterning masks 31 may serve as protection masks for protecting the stacks 20, while the patterning masks 32 may serve as etching masks for forming the stacks 20 from the starting material stack 2 (see also FIG. 2). The patterning masks 31 may be made of a material different from that of the patterning masks 32. In some embodiments, the patterning masks 31 may include silicon nitride, and the patterning masks 32 may include silicon oxide. Other suitable materials for forming the patterning masks 31, 32 are within the contemplated scope of the present disclosure.

The starting material stack 2 (see FIG. 2) is patterned into the stacks 20 and a base 11 through the mask units 30. Specifically, the first nanosheet material layers 210 are formed into first nanosheet layers 21, the second nanosheet material layers 220 are formed into second nanosheet layers 22, and the substrate material layer 10 is formed into mesa regions 12 and the base 11. Each of the stacks 20 includes corresponding ones of the first nanosheet layers 21, corresponding ones of the second nanosheet layers 22 and a corresponding one of the mesa regions 12. Each of the stacks 20 is disposed on the base 11. In some embodiments, each of the stacks 20 may have a width along the Y direction ranging from about 5 nm to about 120 nm. In some embodiments, the stacks 20 are spaced apart from each other along the Y direction by a distance ranging from about 20 nm to about 60 nm. The width of the stacks 20, and the spaced apart distance between any two adjacent ones of the stacks 20 may be varied according to practical needs and product design.

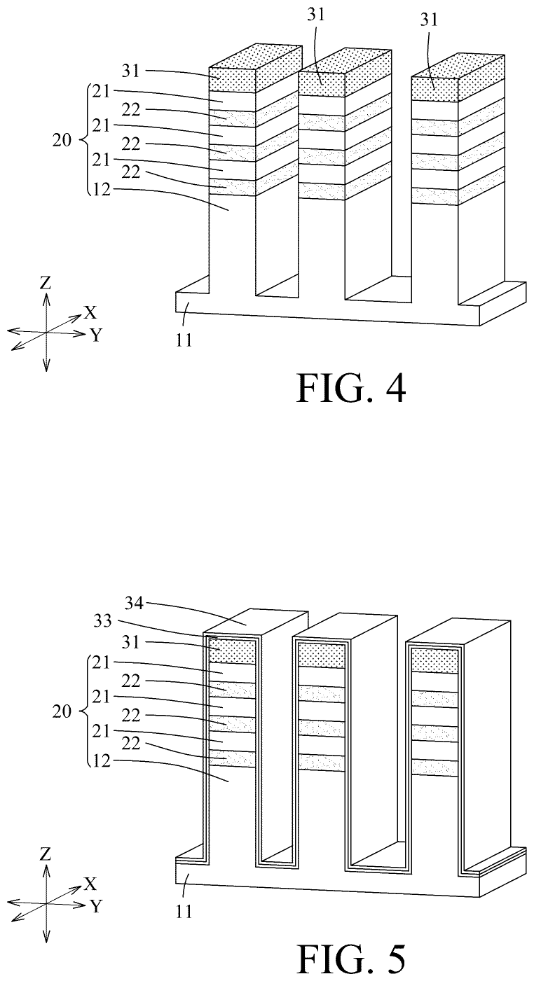

Referring to FIG. 1 and the example illustrated in FIG. 4, the method 100 proceeds to step 103, where the patterning masks 32 shown in FIG. 3 are removed, while the patterning masks 31 remain on the stacks 20. Any suitable removing processes, such as dry etching, but is not limited thereto, may be employed to remove the patterning masks 32.

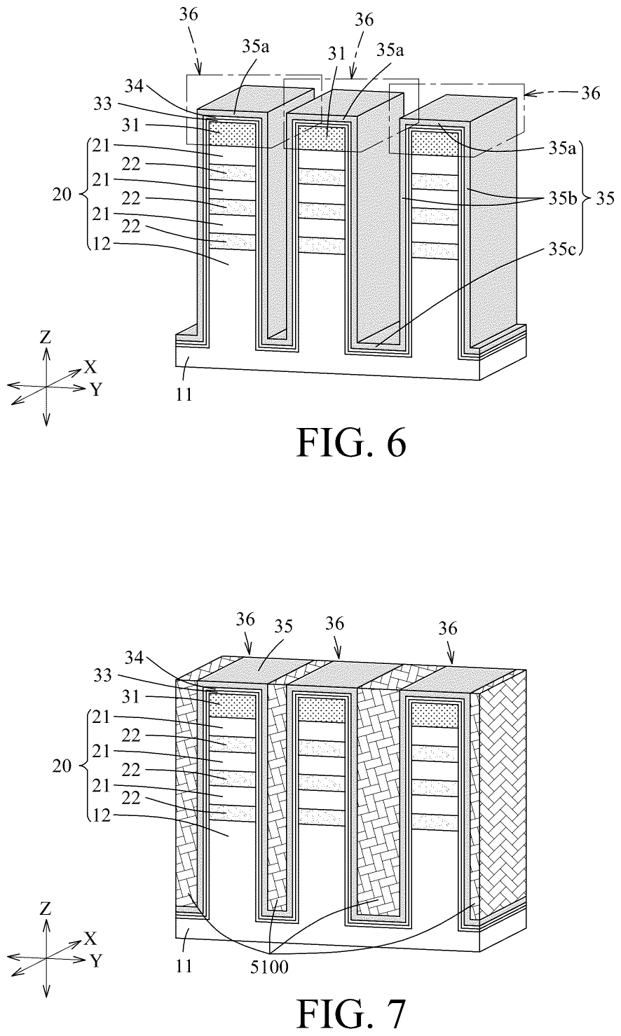

Referring to FIG. 1 and the example illustrated in FIG. 6, the method 100 proceeds to step 104, where a protection film 35 is formed. In some embodiments, step 104 merely involves formation of the protection film 35, while in other embodiments, step 104 may include two sub-steps as illustrated in FIGS. 5 and 6.

Referring to FIG. 5, prior to forming the protection film 35, a silicon liner 33 and a silicon oxide liner 34 may be first sequentially formed over the structure shown in FIG. 4 in a conformal manner. The silicon liner 33 is configured to reduce oxidation of the stacks 20. In some embodiments, the silicon liner 33 may have a thickness ranging from about 0.5 nm to about 4 nm. The silicon oxide liner 34 is configured to reduce stress between the protection film 35 and the silicon liner 33. In some embodiments, the silicon oxide liner 34 may have a thickness ranging from about 0.5 nm to about 2 nm. In some embodiments, the silicon oxide liner 34 may be omitted.

Referring to FIG. 6, the protection film 35 is formed over the structure shown in FIG. 5. The protection film 35 may include one of silicon nitride, silicon carbonitride, silicon oxycarbide, silicon oxycarbonitride, silicon carbide, other suitable materials, and combinations thereof. In some embodiments, the protection film 35 includes silicon carbonitride. The protection film 35 may have a thickness ranging from about 1 nm to about 15 nm, such as about 3 nm to about 5 nm, so that in cooperation with the patterning mask 31, the protection film 35 and the patterning mask 31 may provide sufficient protection effect to the stacks 20 (will be further described later). The protection film 35 may be formed in a conformal manner using any suitable deposition process, such as chemical vapour deposition (CVD), or atomic layered deposition (ALD), but are not limited thereto. Other suitable materials, thickness ranges or deposition processes are within the contemplated scope of the present disclosure.

The protection film 35 includes protection caps 35a that are respectively formed over the patterning masks 31, and protection liners 35b, 35c that are formed on the base 11 and between two adjacent ones of the stacks 20 to interconnect two adjacent ones of the protection caps 35a. For instance, the protection caps 35a are formed on top surfaces and sidewalls of the patterning masks 31, the protection liners 35b are formed on sidewalls of the stacks 20, and the protection liners 35c are formed on the base 11.

After completing step 104, the protection film 35 is formed, and stack coverings 36 are obtained. Each of the stack coverings 36 includes one of the patterning masks 31 and a corresponding one of the protection caps 35a. In some embodiments, each of the stack coverings 36 further includes a corresponding portion of the silicon liner 33 and a corresponding portion of the silicon oxide liner 34 that are disposed between the one of the patterning masks 31 and the corresponding protection cap 35a. Each of the stack coverings 36 covers and protects a corresponding one of the stacks 20.

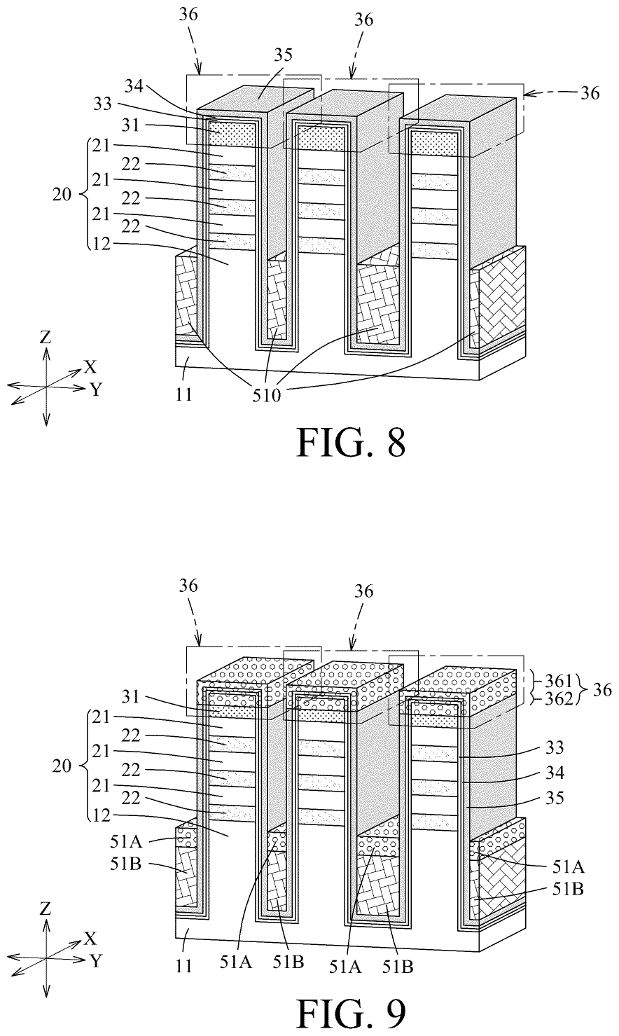

Referring to FIG. 1 and the example illustrated in FIG. 8, the method 100 proceeds to step 105, where isolation features 510 are formed. In some embodiments, step 105 may include two sub-steps as illustrated in FIGS. 7 and 8.

Referring to FIG. 7, isolation material layers 5100 are obtained by depositing an isolation material (not shown) over the structure show in FIG. 6, and removing an excess amount of the isolation material to expose portions of the protection film 35, followed by an annealing process so that the isolation material layers 5100 respectively fill gaps among the stacks 20. The isolation material may include silicon oxide, other suitable dielectric materials different from the material of the protection film 35, or combinations thereof. The isolation material may be deposited using any suitable deposition processes, such as chemical vapour deposition (CVD), or flowable CVD (FCVD) but are not limited thereto. In some embodiments, the excess amount of the isolation material may be removed using a chemical mechanical planarization (CMP) process, but is not limited thereto. Other suitable materials and/or methods for forming the isolation material layers 5100 are within the contemplated scope of the present disclosure.

Referring to FIG. 8, the isolation material layers 5100 shown in FIG. 7 are recessed to a predetermined height, so as to obtain the isolation features 510. In some embodiments, the isolation features 510 may have an upper surface that is lower than a lower surface of the bottommost one of the second nanosheet layers 22 of each of the stacks 20, so as to facilitate performing of subsequent steps.

By completing step 105, the isolation features 510 are each formed to be spaced apart from an adjacent one of the stacks 20, or the base 11 by the protection film 35 (and the silicon liner 33 and the silicon oxide liner 34). The protection film 35 is in direct contact with sidewalls and bottom surfaces of the isolation features 510.

Referring to FIG. 1 and the example illustrated in FIG. 9, the method 100 proceeds to step 106, where an ion implantation process is performed to form top portions of the isolation features 510 (see FIG. 8) into isolation protection elements 51A. In some embodiments, the isolation protection elements 51A may each have a thickness ranging from about 0.5 nm to about 50 nm, so as to provide sufficient protection to lower portions of the isolation features 510. The lower portions are not doped and are denoted as the isolation elements 51B.

In the ion implantation process, any suitable implantation dopants are doped into the top portions of the isolation features 510 such that the isolation protection elements 51A are resistive to oxide etching. In some embodiments, the implantation dopants may include one of silicon, carbon, and a combination thereof. In some embodiments, a dosage of each of silicon and/or carbon may range from about 1×10¹³ atom/cm³ to about 5×10¹⁶ atom/cm³. In some embodiments, energy (accelerating voltage) of the ion implantation process may range from about 0.1 kV to about 10 kV, so as to effectively dope a desired amount of silicon and/or carbon into the isolation features, without affecting other elements of the structure, such as the stacks 20.

Doping of silicon permits formation of Si—Si bond, and thus increases the amount of Si—Si bond in the top portions of the isolation features 510. Doping of carbon permits conversion of Si—Si bond into Si—C bond. The aforementioned bonds, especially Si—C bond, are resistive to oxide etching process, in which etchants, e.g., hydrogen fluoride etchants are involved. As such, the isolation protection elements 51A doped with silicon and/or carbon may effectively prevent the silicon oxide isolation elements 51B from being damaged in oxide etching process(es) performed subsequently, so that the silicon oxide isolation elements 51B can be retained. In some embodiments, the ion implantation may be performed by sequentially doping silicon and carbon into the top portions of the isolation features 510, so that the isolation protection elements 51A obtained thereby may achieve a superior resistivity to oxide etching, so as provide better protection to the silicon oxide isolation elements 51B.

In some embodiments, as carbon is doped into the silicon oxide isolation features 510, the isolation protection elements 51A obtained may have a carbon content greater than a carbon content of the isolation elements 51B by for instance, about 3 atomic % to 5 atomic %, but is not limited thereto. The carbon content may be examined by for instance, wavelength dispersive X-ray spectroscopy (WDS), auger electron spectroscopy (AES), or energy-dispersive x-ray spectroscopy (EDS) but are not limited thereto.

In some embodiments, carbon and/or silicon is (are) directed to top surface of the structure shown in FIG. 8 along the Z direction. In this sense, the stack coverings 36, which are respectively located on top of the stacks 20, are also subjected to the ion implantation process. The stack coverings 36 serve as protection coverings to the stacks 20, so that the stacks 20, especially the first nanosheet layers 21 thereof (which will be formed into channel nanosheets 21A of nanosheet transistors 301 as shown in FIG. 25) are refrained from being affected by the ion implantation process.

In some embodiments, as shown in FIG. 9, in the ion implantation process, the implantation dopants are merely doped in upper parts 361 of the stack coverings 36 but are refrained from reaching lower parts 362 of the stack covering 36 so as to prevent the stacks 20 from being damaged by the ion implantation process.

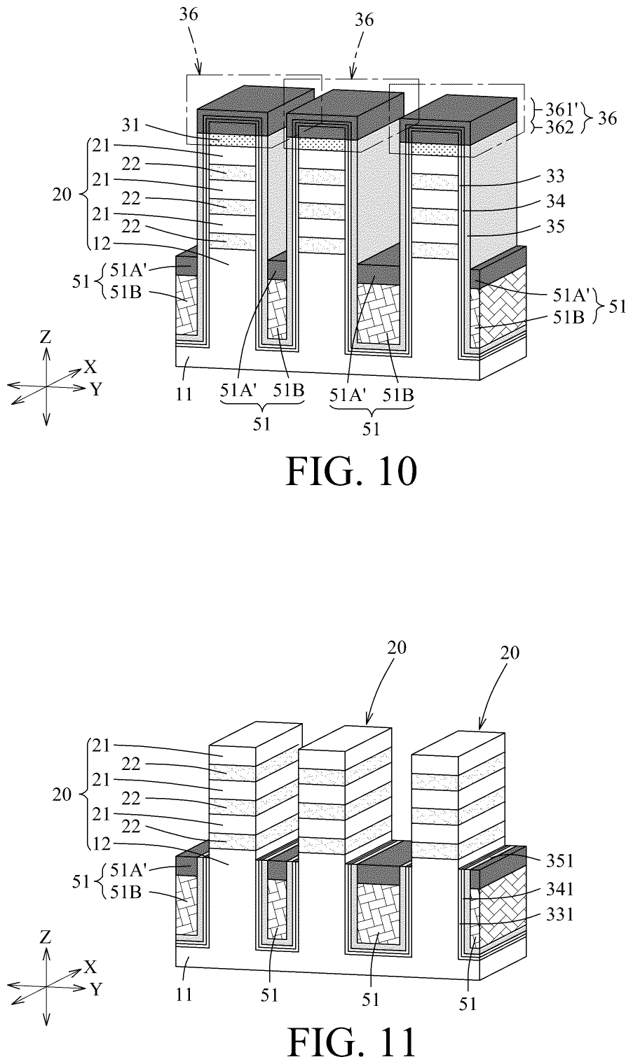

Referring to FIG. 1 and the example illustrated in FIG. 10, the method 100 proceeds to step 107, where an annealing process is performed to treat the isolation protection elements, which are hereinafter denoted by the numeral 51A′.

The annealing process recovers any defects incurred during the ion implantation process performed in step 106. In some embodiments, the annealing process may be conducted at a temperature ranging from about 200° C. to about 1200° C. In some embodiments, the annealing process is performed with a time period ranging from about 0.1 second to about 1000 seconds. Such temperature range and time period allow effective recovery of the defects, without causing diffusion of germanium in the second nanosheet layers 22 (made of silicon germanium) into the first nanosheet layers 21 (made of silicon). In addition, it is found that the annealed isolation protection elements 51A′ provides enhanced resistivity to oxide etching, i.e, improved protection to the silicon oxide isolation elements 51B against any oxide etching processes performed in subsequent steps. By completing step 107, isolation units 51 are thereby obtained, each of which includes one of the isolation protection elements 51A′ that are annealed, and a corresponding one of the isolation elements 51B.

The upper parts 361 of the stack coverings 36 (see FIG. 9) are also subjected to the annealing process, and are denoted by the numeral 361′ hereinafter (see FIG. 10). It is noted that the upper parts 361 and the isolation protection elements 51A shown in FIG. 9 are both subjected to the ion implantation process, and thus have the same shading, and that the upper parts 361 and the isolation protection elements 51A include different materials. Similarly, the upper parts 361′ and the isolation protection elements 51A′ shown in FIG. 10 have the same shading but include different materials. In some embodiments, each of the upper parts 361′ and the isolation protection elements 51A′ may include silicon nitride, silicon carbonitride, silicon oxycarbide, silicon oxycarbonitride, silicon carbide, or combinations thereof. In some embodiments, the upper parts 361 or 361′ or the stack coverings 36 include carbon-doped nitride-containing dielectric material (e.g., silicon carbonitride) while the isolation protection elements 51A or 51A′ include carbon-doped oxide-containing dielectric material (e.g., silicon oxycarbide). As such, during removal of the stack coverings 36 in the next step, the isolation protection elements 51A′ remain intact.

Referring to FIG. 1 and the example illustrated in FIGS. 10 and 11, the method 100 proceeds to step 108, where a removing process is performed to remove the stack coverings 36, parts of the silicon liner 33, parts of silicon oxide liner 34 and parts of the protection film 35 that are located above the isolation units 51. Each of the isolation units 51 is surrounded by a remaining part of the silicon liner, known as a silicon liner part 331, a remaining part of the silicon oxide liner, known as a silicon oxide liner part 341, and a remaining part of the protection film, known as a protection film part 351.

The removing process may employ any suitable techniques known in the art. In some embodiments, an etching process is employed, but is not limited thereto. Other suitable methods for removing the aforementioned elements are within the contemplated scope of the present disclosure.

By completing step 108, the stacks 20 are exposed from the isolation units 51. Specifically, for each of the stacks 20, the first nanosheet layers 21, the second nanosheet layers 22, and a top portion of the mesa region 12 are exposed from the isolation units 51.

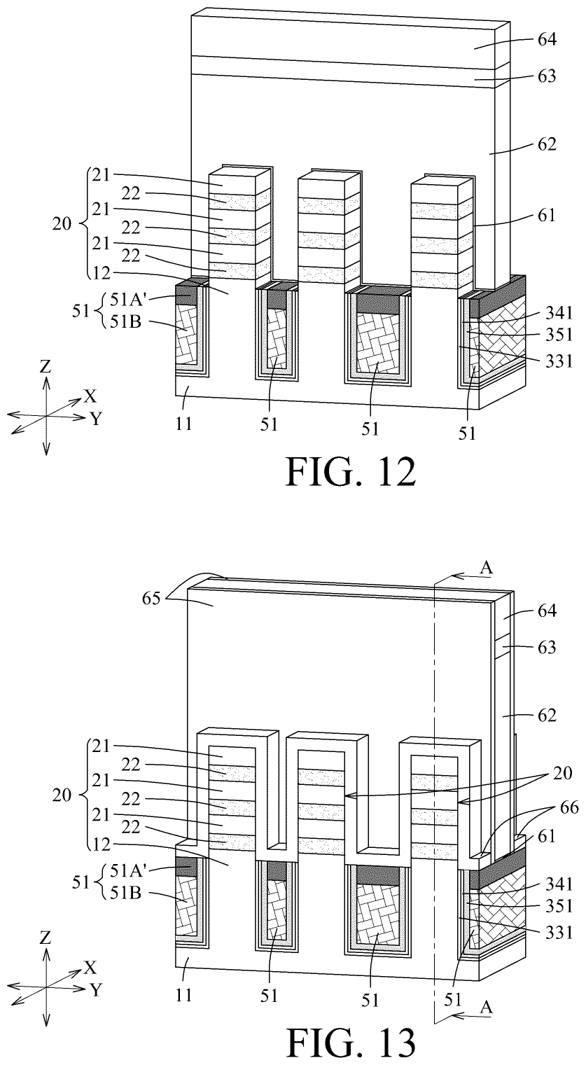

Referring to FIG. 1 and the example illustrated in FIG. 12, the method 100 proceeds to step 109, where a dummy dielectric 61, a dummy gate 62, a polish-stop layer 63, and a hard mask layer 64 are formed over the stacks 20 and the isolation units 51.

In some embodiments, step 109 includes: sequentially depositing a dummy dielectric material (for forming the dummy dielectric 61) and a dummy gate material (for forming the dummy gate 62) over the stacks 20 and the isolation units 51 in a conformal manner; performing a planarization process (e.g., chemical mechanical polishing (CMP)) to obtain a planar upper surface of the dummy gate material; depositing a polish-stop material (for forming the polish-stop layer 63) on the planar upper surface of the dummy gate material; forming the hard mask layer 64 over the polish-stop material; and patterning the dummy dielectric material, the dummy gate material, the polish-stop material through the hard mask layer 64, thereby obtaining the structure shown in FIG. 12.

In some embodiments, the dummy dielectric material may include a dielectric material, such as silicon oxide, but is not limited thereto. The dummy gate material may include polycrystalline silicon, or the like, but is not limited thereto. The polish-stop layer 63, and the hard mask layer 64 are made of different materials, and may each include silicon nitride, silicon oxide, silicon oxynitride, or the likes, but are not limited thereto. Other suitable materials and methods for forming the dummy dielectric 61, the dummy gate 62, the polish-stop layer 63, and the hard mask layer 64 are within the contemplated scope of the present disclosure.

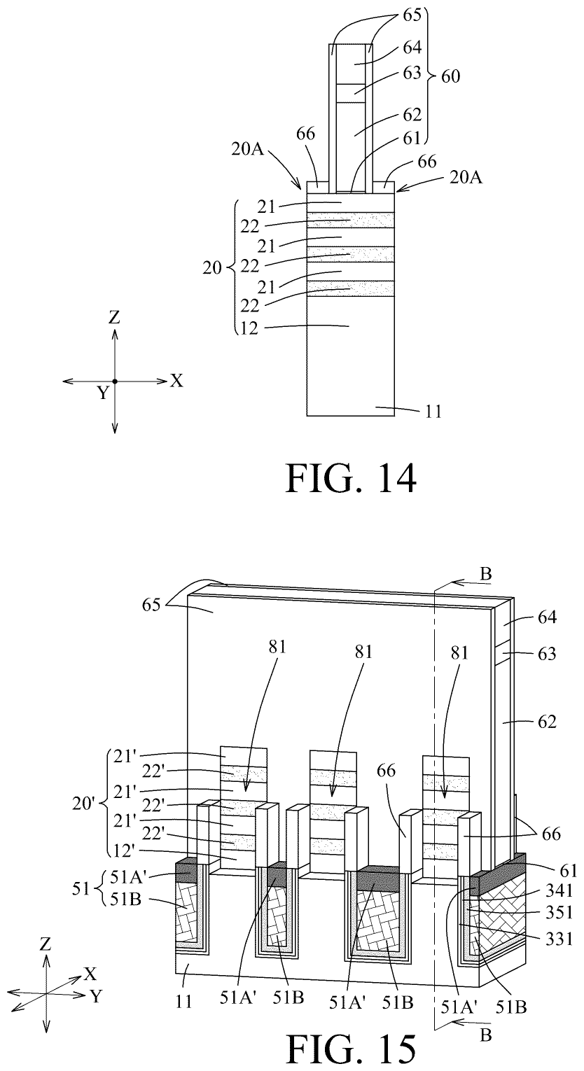

Referring to FIG. 1 and the examples illustrated in FIGS. 13 and 14, the method 100 proceeds to step 110, where a pair of gate spacers 65 is formed at opposite sides of a stack including the dummy dielectric 61, the dummy gate 62, the polish-stop layer 63, and the hard mask layer 64 along the X direction, thereby obtaining a gate structure 60. FIG. 14 is a cross-sectional view of line A-A shown in FIG. 13 in accordance with some embodiments.

In some embodiments, step 110 includes conformally forming a gate spacer material (not shown) over the structure shown in FIG. 12, and an anisotropic etching to selectively remove any of the gate spacer material that is disposed on the hard mask layer 64, thereby obtaining the gate spacers 65 and fin sidewalls 66. In some embodiments, the gate spacer material includes a dielectric material, such as a silicon carbon-containing dielectric material, a silicon oxide-containing material, silicon nitride, other suitable materials, or combinations thereof. Other suitable materials and/or methods for forming the gate spacers 65 and the fin sidewalls 66 are within the contemplated scope of the present disclosure.

By completing step 110, as shown in FIGS. 13 and 14, the gate structure 60 including the dummy dielectric 61, the dummy gate 62, the polish-stop layer 63, the hard mask layer 64 and the pair of the gate spacers 65 is therefore obtained. The pair of the gate spacers 65 is formed across the stacks 20 and the isolation units 51 to sandwich the dummy dielectric 61, the dummy gate 62, the polish-stop layer 63, and the hard mask layer 64. Each of the stacks 20 has two portions 20A that are opposite to each other and that are located at two opposite sides of the gate structure 60 along the X direction. In some embodiments, a pair of the fin sidewalls 66 is formed at opposite sides of the pair of the gate structure 60. The fin sidewalls 66 are conformally formed along the two portions 20A of the stacks 20, and the isolation units 51.

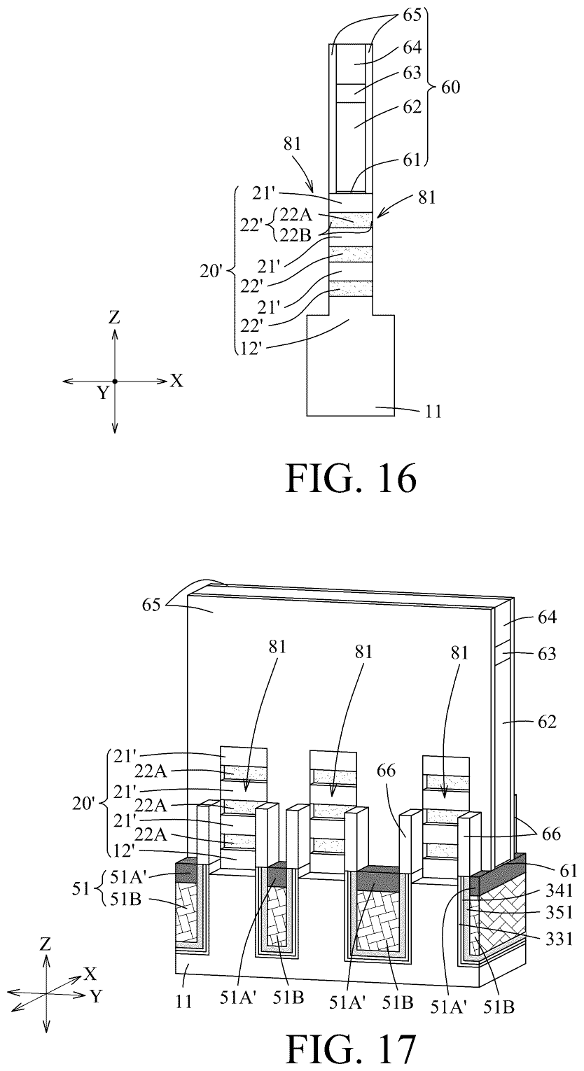

Referring to FIG. 1 and the examples illustrated in FIGS. 15 and 16, the method 100 proceeds to step 111, where the two portions 20A (see FIGS. 13 and 14) of each of the stacks 20 are removed to from source/drain recesses 81. FIG. 16 is a cross-sectional view of line B-B shown in FIG. 15, and is subsequent to the structure shown in FIG. 14 in accordance with some embodiments.

In some embodiments, step 111 may include: protecting the gate structure 60 using a photoresist (not shown); and performing an etching process to remove the two portions 20A of each of the stacks 20, to thereby form the source/drain recesses 81. In the etching process, before removing the two portions 20A of each of the stacks 20, portions of the fin sidewalls 66 that surround upper parts of the two portions 20A of the stacks 20, and portions of the fin sidewalls 66 that are located on top of the isolation units 51 shown in FIG. 13 are first removed, leaving the fin sidewalls 66 recessed as shown in FIG. 15. In some embodiments, the recessed fin sidewalls 66 may have a height ranging from about 3 nm to about 40 nm, but is not limited thereto. Other suitable methods for forming the source/drain recesses 81 are within the contemplated scope of the present disclosure.

By completing step 111, as shown in FIG. 16, the stacks 20 (see FIG. 14) are formed into patterned stacks 20′, the first nanosheet layers 21 are formed into first nanosheets 21′, and the second nanosheet layers 22 are formed into second nanosheets 22′. Each of the second nanosheets 22′ has a main part 22A disposed below the dummy gate 62, and two end regions 22B disposed at two opposite sides of the main part 22A and below the gate spacers 65. In addition, for each of the patterned stacks 20′, a top portion of the mesa region may also be recessed, and is denoted by the numeral 12′.

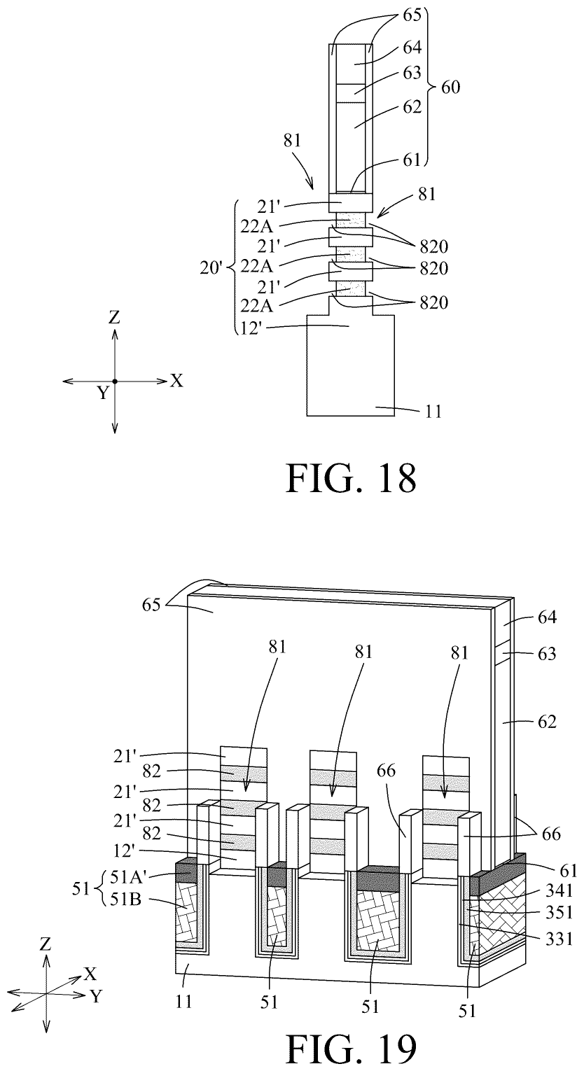

Referring to FIG. 1 and the examples illustrated in FIGS. 17 and 18, the method 100 proceeds to step 112, where the two end regions 22B of each of the second nanosheets 22′ (see FIG. 16) are removed to form multiple pairs of lateral recesses 820 in each of the patterned stacks 20′, remaining the main parts 22A. FIGS. 17 and 18 illustrate structures respectively subsequent to the structures shown in FIGS. 15 and 16.

Any suitable processes known in the art, such as a suitable etching process, but is not limited thereto, may be used to remove the end regions 22B, thereby forming the lateral recesses 820 below the gate spacers 65.

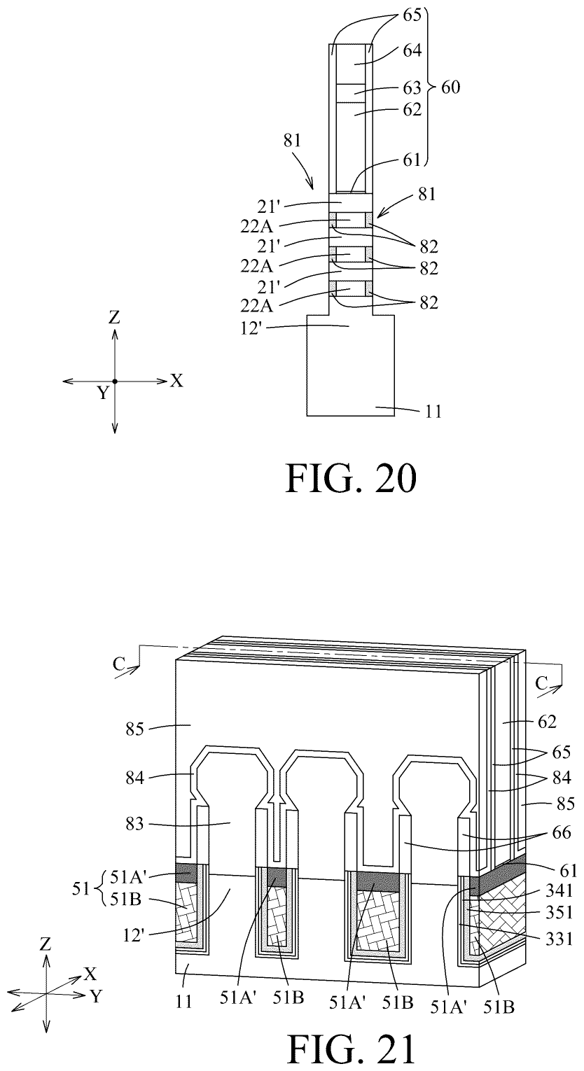

Referring to FIG. 1 and the examples illustrated in FIGS. 19 and 20, the method 100 proceeds to step 113, where multiple pairs of inner spacers 82 are formed respectively in the multiple pairs of the lateral recesses 820 (see FIG. 18). FIGS. 19 and 20 illustrate structures respectively subsequent to the structures shown in FIGS. 17 and 18.

Any suitable processes known in the art, such as deposition, followed by etching, may be used to form the inner spacers 82. In some embodiments, the inner spacers 82 may include a dielectric material such as silicon oxide, silicon nitride, silicon oxynitride, silicon carbide, or the likes, or combinations thereof. Other suitable materials and/or methods for forming the inner spacers 82 are within the contemplated scope of the present disclosure.

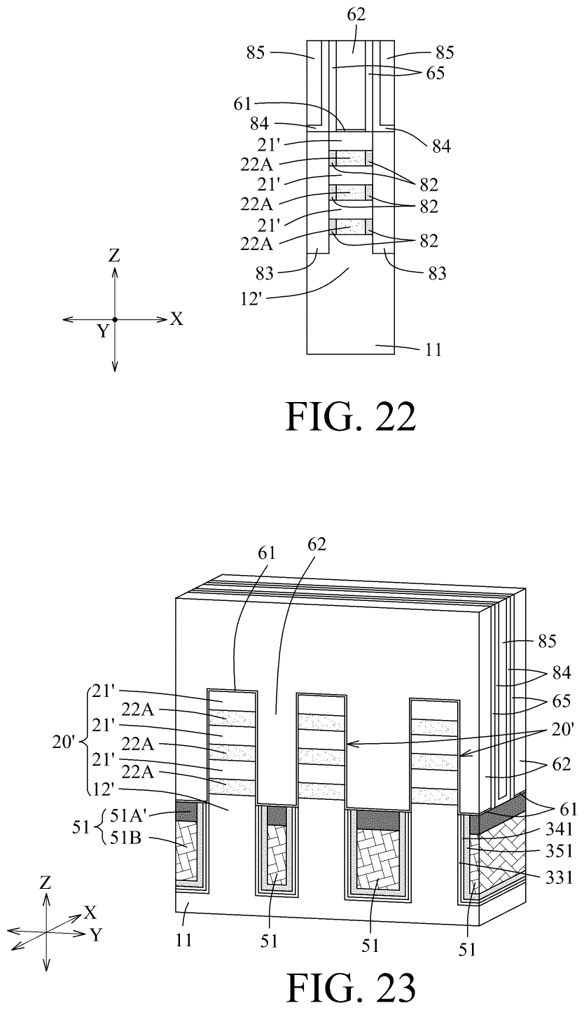

Referring to FIG. 1 and the examples illustrated in FIGS. 21, 22 and 23, the method 100 proceeds to step 114, where source/drain portions 83 are respectively formed in the source/drain recesses 81 (see also FIGS. 19 and 20). FIGS. 21 and 22 illustrate structures respectively subsequent to the structures shown in FIGS. 19 and 20. FIG. 23 is a cross-sectional view along the line C-C shown in FIG. 21 in accordance with some embodiments. Source/drain portion(s) may refer to a source or a drain, individually or collectively dependent upon the context.

In some embodiments, step 114 includes: performing a pre-cleaning process to the source/drain recesses 81 (see FIGS. 19 and 20); forming the source/drain portions 83 using an epitaxy growth process through e.g., a CVD deposition process, but is not limited thereto; forming a contact etch stop layer (CESL) 84 over the source/drain portions 83 to be in contact with the gate spacers 65; and forming an interlayer dielectric (ILD) 85 over the CESL 84. In some embodiments, the CESL 84 and the ILD 85 are formed by sequentially depositing two material layers (respectively for forming the CESL 84 and the ILD 85) over the source/drain portions 83 and the gate structure 60 (see also FIG. 20), followed by a planarization process (such as CMP) to remove the hard mask layer 64 and the polish-stop layer 63 (see FIG. 20), and thus the dummy gate 62 is exposed after step 114 (see also FIGS. 22 and 23).

In some embodiments, the pre-cleaning process may use etchants such as hydrofluoric acid, to remove any silicon oxide materials, or the likes that are present in the source/drain recesses 81 (see FIGS. 19 and 20). In the present disclosure, the silicon oxide isolation elements 51B are respectively covered by the isolation protection elements 51A′. The isolation protection elements 51A′, in step 106, are each doped with silicon and/or carbon and are resistive to the pre-cleaning etchants, and thus can protect the silicon oxide elements 51B. As such, the isolation elements 51B are not affected by the pre-cleaning etchants and remain intact. In the case that the isolation protection elements 51A′ are not formed, the silicon oxide isolation features (e.g., 510 show in FIG. 8) are affected by the pre-cleaning etchants, and result in loss of portions of the isolation features. Sidewalls of the mesa regions might be exposed, and source/drain portions may also grow from the exposed sidewalls of the mesa regions.

The source/drain portions 83 are each formed in a corresponding one of the source/drain recesses 81 between a corresponding pair of the recessed fin sidewalls 66 and are spaced apart from each other along the Y direction. In some embodiments, upper surfaces of the source/drain portions 83 may be flush with upper surfaces of topmost first nanosheets 21′ of the patterned stacks 20′. In some embodiments, each of the source/drain portions 83 may include multiple epitaxy layers. In certain embodiments, each of the source/drain portions 83 may include silicon, silicon germanium, other suitable materials, or combinations thereof. In other embodiments, each of the source/drain portions 83 may include any suitable dopants (such as n-type dopant(s), or p-type dopant(s)). Other suitable methods and/or processes for forming the source/drain portions 83 are within the contemplated scope of the present disclosure.

In some embodiments, each of the CESL 84 and the ILD 85 may include a dielectric material such as silicon oxide, silicon nitride, or the like, or combinations thereof. The ILD 85 may include a dielectric material different from that of the CESL 84. Other suitable materials for forming the CESL 84 and the ILD 85 are within the contemplated scope of the present disclosure.

FIG. 23 illustrates the cross-sectional view along the dummy gate 62, the patterned stacks 20′ at which the first nanosheets 21′, and the main parts 22A are shown.

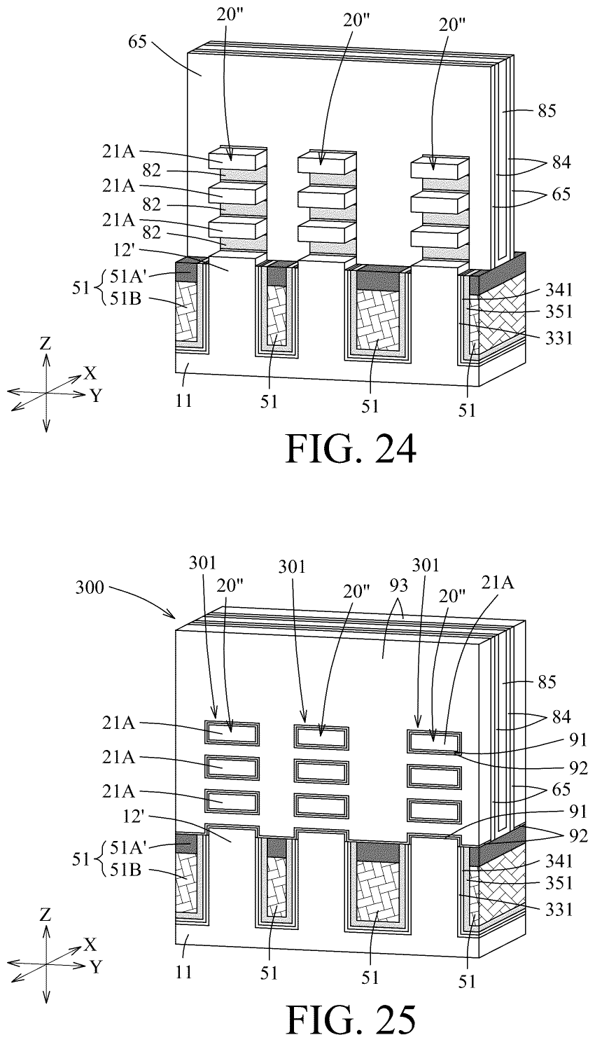

Referring to FIG. 1 and the example illustrated in FIG. 24 which is a structure subsequent to that shown in FIG. 23, the method 100 proceeds to step 115, where the dummy gate 62, the dummy dielectric 61 and the main parts 22A (see FIG. 23) are sequentially removed, and a sheet trimming process is performed to form the first nanosheets 21′ (see FIG. 23) into channel nanosheets 21A. After removing the main parts 22A, the remaining patterned stacks are known as nanosheet stacks 20″. In each of the nanosheet stacks 20″, the channel nanosheets 21A are spaced apart from each other in the Z direction.

In some embodiments, each of the dummy gate 62, the dummy dielectric 61 and the main parts 22A is removed using any suitable techniques and/or etchants known in the art, such as an etching process, but is not limited thereto. After removing these elements, the first nanosheets 21′ are exposed from the gate spacers 65, and the inner spacers 82 are exposed from the first nanosheets 21′ (see FIG. 23).

In some embodiments, the sheet trimming process may include removing any native oxides disposed on the first nanosheets 21′, followed by a suitable etching process to achieve the channel nanosheets 21A with desired dimensions. In some embodiments, before the sheet trimming process, the first nanosheets 21′ (formed from the first nanosheet material layers 210, see FIG. 2) may have a height along the Z direction ranging from about 4 nm to about 9 nm. After the sheet trimming process, the channel nanosheets 21A may have a height along the Z direction ranging from about 3 nm to about 6 nm, but is not limited thereto. The height of each of the first nanosheet material layers 210 and/or the channel nanosheets 21A may be varied according to practical needs and product design. In other embodiments, the sheet trimming process may be omitted.

In step 115, both the removal of the silicon oxide dummy dielectric 61 and the native oxides disposed on the first nanosheets 21′ might involve oxide removing etchants. In this sense, the silicon oxide isolation elements 51B are protected by the oxide-etching-resistive isolation protection elements 51A′, and thus are not affected by the etchants and remain intact. In the case that the isolation protection elements 51A′ are not formed, the silicon oxide isolation features (e.g., 510 show in FIG. 8) are affected by the oxide removing etchants, and result in undesirably additional recessing of the isolation features. Gate electrode formed subsequently (will be described in next step) may also fill the additional recess(es), causing increment of parasitic capacitance of a resultant nanosheet transistor. In the present disclosure, by forming the isolation protection elements 51A′, the isolation units 51 may be retained in steps 114 and 115, and the capacitance of the nanosheet transistors 301 (see FIG. 25) may be reduced by at least approximately 3%

Referring to FIG. 1 and the example illustrated in FIG. 25, the method 100 proceeds to step 116, where interfacial layers 91, a gate dielectric 92, and a gate electrode 93 are formed.

In some embodiments, step 116 may include: forming interfacial layers 91 around the channel nanosheets 21A, respectively; then forming the gate dielectric 92 on the interfacial layers 91 around the channel nanosheets 21A, and on the gate spacers 65, the inner spacers 82; and then forming the gate electrode 93 on the gate dielectric 92, and around the channel nanosheets 21A. In certain embodiments, more specifically, the gate dielectric 92 is formed over the interfacial layers 91, and the structure shown in FIG. 24 to further cover each of the isolation units 51, and a corresponding silicon liner part 331, a corresponding silicon oxide liner part 341 and a corresponding protection film part 351.

The interfacial layer 91 may include a dielectric material such as silicon oxide, silicon nitride, silicon oxynitride, or combinations thereof, but is not limited thereto. The gate dielectric 92 may include a high dielectric constant material (e.g., hafnium oxide), but is not limited thereto. The gate electrode 93 may include a conductive material such as a metal, a metal-containing nitride, a metal-containing silicide, a metal-containing carbides, but is not limited thereto. Other suitable materials and/or processes for forming the interfacial layer 91, the gate dielectric 92 and the gate electrode 93 are within the contemplated scope of the present disclosure.

By completing step 116, the semiconductor structure 300 is obtained, and includes, for instance, three nanosheet transistors 301 (but are not limited thereto). Each of the nanosheet transistors 301 (see FIG. 25) includes one of the nanosheet stacks 20″, two corresponding ones of the source/drain portions 83 (see FIGS. 21 and 22) at two opposite sides of the one of the nanosheet stacks 20″, and a gate unit. Each of the gate units of the nanosheet transistors 301 is constituted by the gate dielectric 92 and the gate electrode 93. The gate units are disposed around the channel nanosheets 21A of the nanosheet stacks 20″. The nanosheet transistors 301 shown in FIG. 25 are gate-all-around

(GAA) nanoasheet transistors, but are not limited thereto. The number, and type of the nanosheet transistors 301 may be varied according to practical needs and product design. In addition, the semiconductor structure 300 further includes the isolation units 51, each of which is disposed between two adjacent ones of the nanosheet transistors 301. Each of the isolation units 51 includes the upper portion 51A′ (known as the isolation protection element), and has a carbon content greater than that of the lower portion (known as the isolation element 51B). For each of the isolation units 51, a bottom surface (adjacent to the base 11) and sidewalls (adjacent to the mesa regions 12′) thereof are surrounded by the protection film part 351.

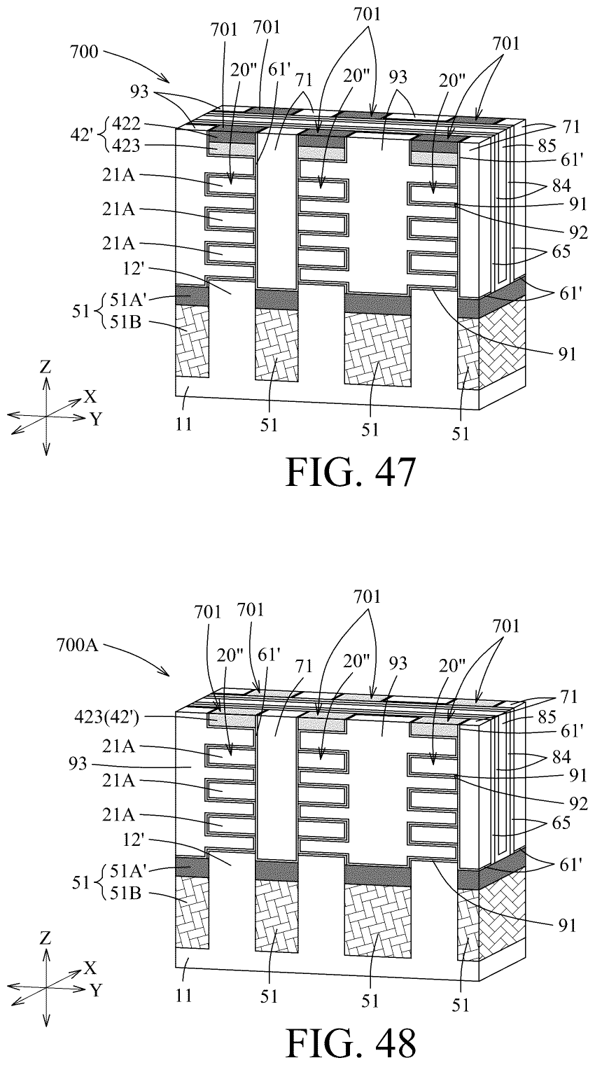

In the semiconductor structure 300 formed using the method 100, the stack coverings 36 (see FIGS. 10 and 11) are removed in step 108, and are not present in the resultant semiconductor structure 300. In the following paragraphs, a method 600 (see FIG. 26) is described to manufacture a semiconductor structure 700 or 700A (see FIGS. 47 or 48). The semiconductor structures 300 and 700 (or 700A) are similar in terms of both having the isolation units 51, each of which includes the upper portion 51A′ with a higher carbon content and the lower portion 51B with a lower carbon content. The semiconductor structure 700 (or 700A) differs from the semiconductor structure 300 in that the semiconductor structure 700 includes other stack coverings, which are denoted as patterned stack coverings 42′ (see FIGS. 47 or 48), and which are respectively disposed on the topmost channel nanosheets 21A of the nanosheet transistors 301.

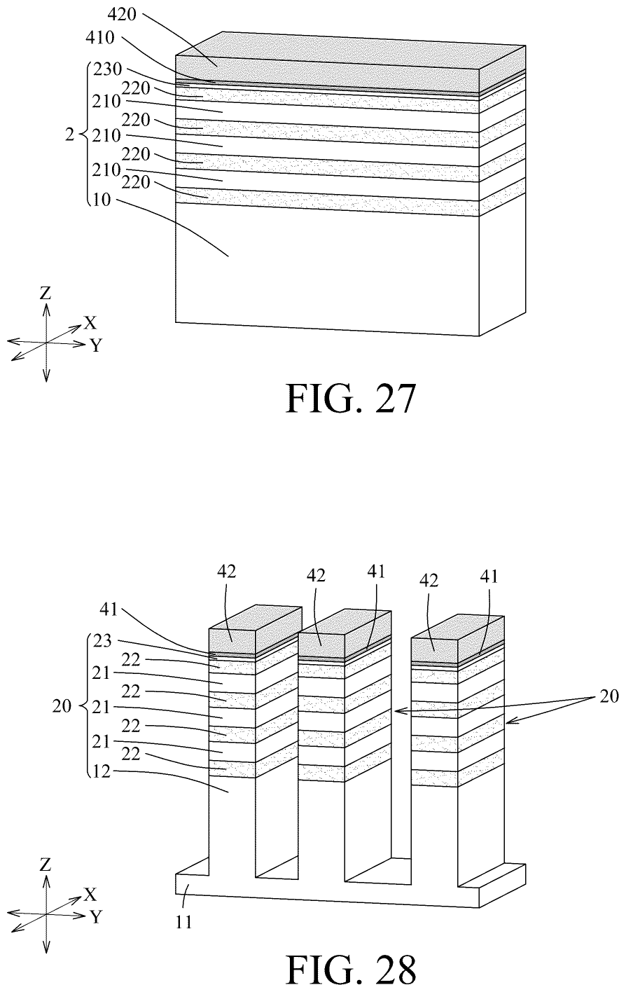

FIGS. 26 to 48 describe a process flow that the stack coverings are retained during the manufacturing process of the semiconductor structure (for example, the semiconductor structure 700 or 700A shown in FIGS. 47 or 48). FIG. 26 is a flow diagram illustrating the method 600 for manufacturing the semiconductor structure 700 in accordance with some embodiments. FIGS. 27 to 48 illustrate schematic views of intermediate stages of the method 600 in accordance with some embodiments. Some repeating structures are omitted in FIGS. 27 to 48 for the sake of brevity. Additional steps can be provided before, after or during the method, and some of the steps described herein may be replaced by other steps or be eliminated.

Referring to FIG. 26 and the example illustrated in FIG. 27, the method 600 begins at step 601, where a starting material stack 2, and a stack protection material layer 420 are formed.

The starting material stack 2 formed in step 601 includes a substrate material layer 10, first and second nanosheet material layers 210, 220 that are similar to those described in step 101 with reference to FIG. 2, and thus materials thereof are omitted for the sake of brevity.

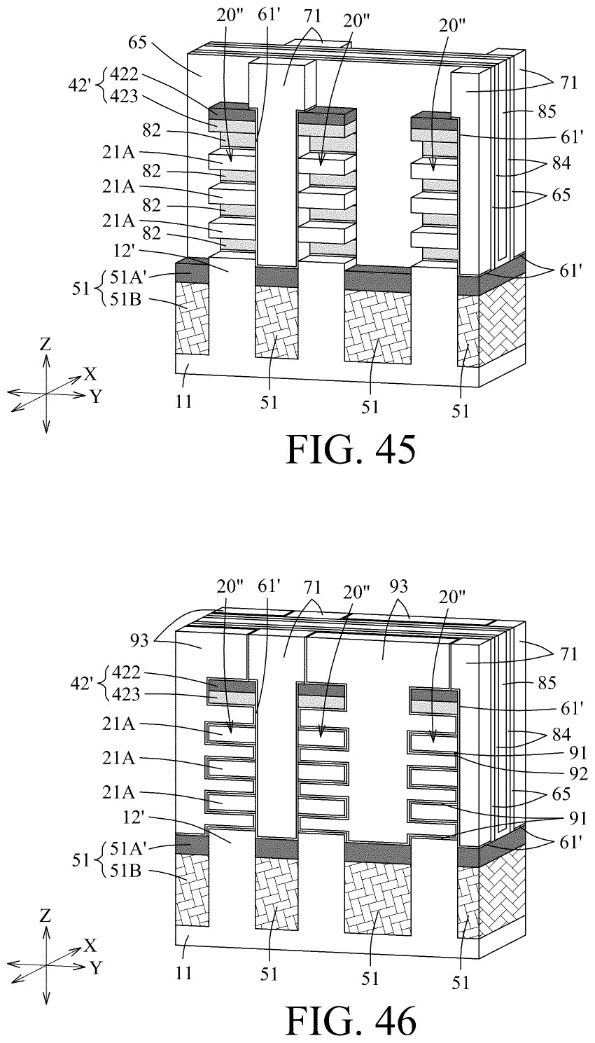

In the starting material stack 2 of step 601, both a topmost and a bottommost one of the nanosheet material layers 210, 220 are the second nanosheet material layers 220, and a number of the second nanosheet material layers 220 (which will be removed to accommodate a gate electrode 93, see FIGS. 45 and 46) is greater than a number of the first nanosheet material layers 210 (which will be formed into channel nanosheets 21A, see FIGS. 45 to 48). For instance, as shown in FIG. 27, there are three first nanosheet material layers 210, and four second nanosheet material layers 220. Such configuration allows formation of the gate electrode 93 around the channel nanosheets 21A (see FIG. 46), especially between each of the topmost channel nanosheets 21A and a corresponding one of patterned stack coverings 42′ (see FIGS. 46 or 47) (which are formed from the stack protection material layer 420). In some embodiments, the starting material stack 2 in step 601 further includes a covering material layer 230 that is disposed on the nanosheet material layers 210, 220 in the starting material stack 2, and that may be made of the same material as of the first nanosheet material layers 210. Unlike the first nanosheet material layers 210, the covering material layer 230 will not be formed into the channel nanosheets, but merely to serve as a sacrificial layer to allow topmost ones of lateral recesses 821 (will be described later, see FIG. 38) to be formed with a desired profile. The covering material layer 230 may have a thickness much thinner than the first/second nanosheet material layers 210, 220.

In addition, a stress releasing material layer 410 and the stack protection material layer 420 are sequentially formed on the covering material layer 230.

The stress releasing material layer 410 is configured to release stress of the stack protection material layer 420, so as to avoid wafer bending. In some embodiments, the stress releasing material layer 410 may include silicon oxide, but is not limited thereto. The stress releasing material layer 410 may have a thickness ranging from about 0.5 nm to about 3 nm, such as approximately 1 nm.

The stack protection material layer 420 is configured to serve as a protection hard mask, and will be formed into the patterned stack coverings 42′ that are located above the channel nanosheets 21A in the semiconductor structure 700 (see FIG. 47). The stack protection material layer 420 may be any suitable dielectric material. The stack protection material layer 420 may have a thickness ranging from about 1 nm to about 50 nm, such as about 3 nm to about 20 nm, or about 10 nm to about 15 nm, so as to provide sufficient protection to stacks 20 during subsequent ion implantation process (see FIG. 30).

Other details regarding step 601 are similar to those described in step 101 and FIG. 2, and thus are not repeated for the sake of brevity.

Referring to FIG. 26 and the example illustrated in FIG. 28, the method 600 proceeds to step 602, where the starting material stack 2 (see FIG. 27) is patterned into stacks 20 and a base 11, the stack protection material layer 420 is patterned into stack coverings 42, and the stress releasing material layer 410 is patterned into stress releasing layers 41.

The first nanosheet material layers 210, the second nanosheet material layers 220, and the covering material layer 230 are respectively patterned into first nanosheet layers 21, second nanosheet layers 22, and covering layers 23. The substrate material layer 10 is patterned into mesa regions 12 and a base 11. Each of the stacks 20 includes corresponding ones of the first and second nanosheet layers 21, 22, a corresponding one of the covering layers 23 disposed on the corresponding first and second nanosheet layers 21, 22, and a corresponding one of the mesa regions 12 disposed beneath the first and second nanosheet layers 21, 22. The stacks 20 are disposed on the base 11. Each of the stacks 20 is covered by a corresponding one of the stack coverings 42. Each of the stress releasing layers 41 is interposed between one of the stacks 20 and a corresponding one of the stack coverings 42.

In some embodiments, step 602 may include: forming a patterned photoresist (not shown) on the stack protection material layer 420 (see FIG. 27); patterning the starting material stack 2, the stress releasing material layer 410 and the stack protection material layer 420 through the patterned photoresist; and removing the patterned photoresist. Other suitable methods for forming the stacks 20, the stress releasing layers 41 and the stack coverings 42 are within the contemplated scope of the present disclosure.

By completing step 602, the stack coverings 42 are obtained. The stack coverings 42 formed in step 602 and the stack coverings 36 (see FIG. 6) formed in step 104 are both configured to prevent the stacks 20 from being affected in the subsequent ion implantation process (i.e., step 106 is described with reference to FIG. 9, and step 604 will be described with reference to FIG. 30). The two stack coverings 36, 42 are respectively formed using different materials and different processes, are thus are denoted with different numerals. In some embodiments, the stack coverings 42 formed in step 602 are each a relatively thick layer of silicon carbonitride, while the stack coverings 36 formed in step 104 each includes a relatively thin layer of silicon carbonitride (e.g., a corresponding one of the protection caps 35a) and a layer of silicon nitride (e.g., a corresponding one of the patterning masks 31).

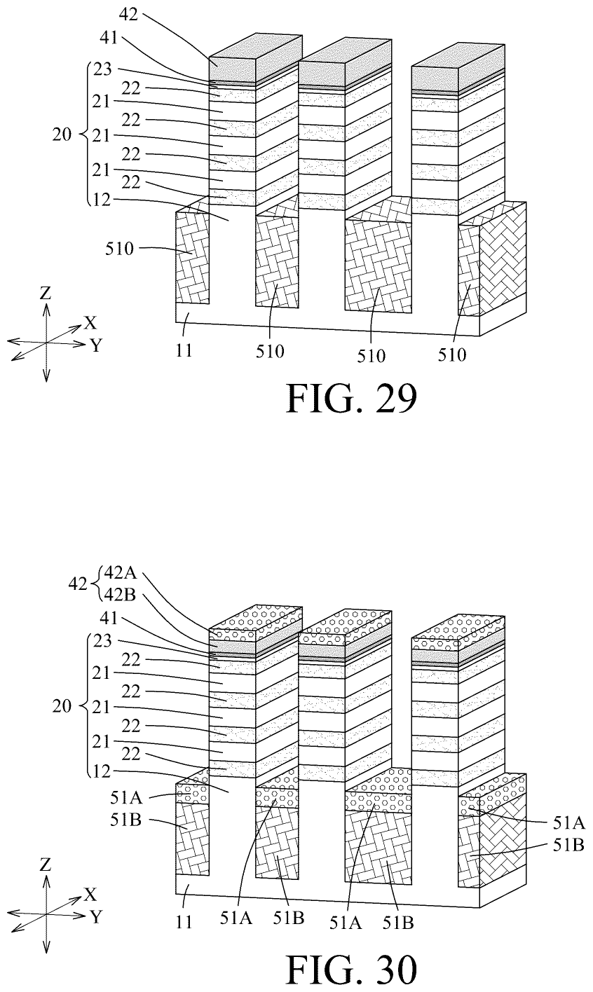

Referring to FIG. 26 and the example illustrated in FIG. 29, the method 600 proceeds to step 603, where isolation features 510 are formed.

Materials and methods for preparing the isolation features 510 in step 603 are similar to those described in step 105 of the method 100 with reference to FIGS. 7 and 8, and thus are not repeated for the sake of brevity. Please note that the isolation features 510 are made of a material different from that of the stack protection material layer 420.

The isolation features 510 formed in step 603 are each in direct contact with the adjacent mesa regions 12. In contrast, the isolation features 510 formed in step 105 of the method 100 are each in contact with the adjacent mesa regions 12 through at least the protection film 35 (in some embodiments, also through the silicon oxide liner 34 and the silicon liner 33).

Referring to FIG. 26 and the example illustrated in FIG. 30, the method 600 proceeds to step 604, where an ion implantation process is performed to form top portions of the isolation features 510 (see FIG. 29) into isolation protection elements 51A.

Similar to step 106 of the method 100 with reference to FIG. 9, the ion implantation process of step 604 forms the top portions of the isolation features 510 into the isolation protection elements 51A, while lower portions of the isolation features 510 are not doped and are denoted as the isolation elements 51B. Details of the ion implantation process are not repeated for the sake of brevity.

In addition, similar to the stack coverings 36 (see FIG. 9) in step 106 of the method 100, in step 604, the stack coverings 42 are also subjected to the ion implantation process, so as to protect the stacks 20, and such that, for instance, the first and second nanosheet layers 21, 22 of the stacks 20, are refrained from and are not affected by the ion implantation process. In each of the stack coverings 42, an upper part thereof is doped and denoted as the doped stack covering 42A, while a lower part thereof is undoped, and denoted as the undoped stack covering 42B.

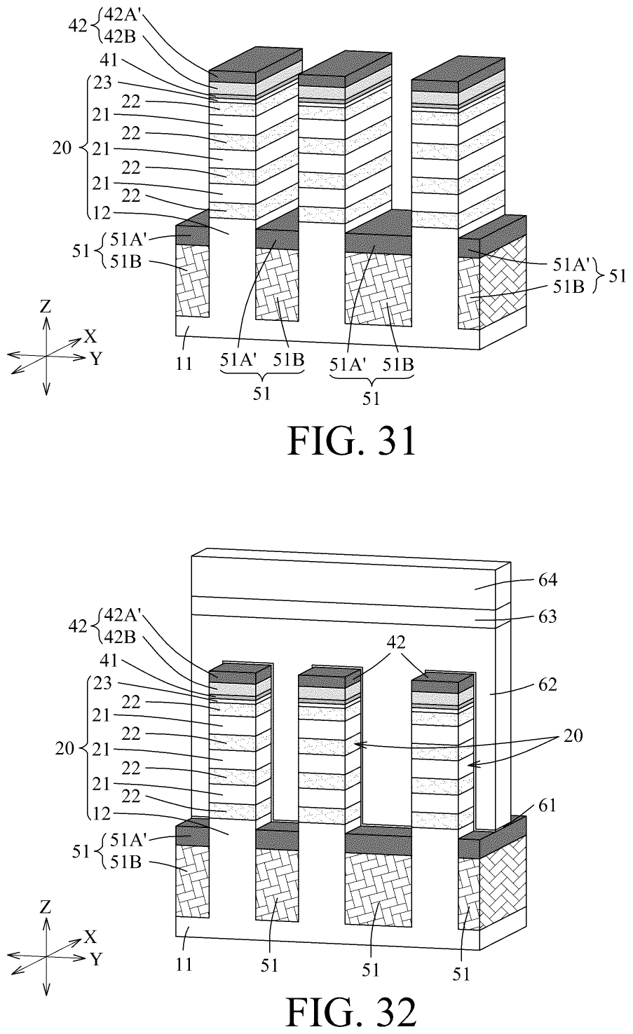

Referring to FIG. 26 and the example illustrated in FIG. 31, the method 600 proceeds to step 605, where an annealing process is performed to treat the isolation protection elements, which are hereinafter denoted by the numeral 51A′.

The annealing process of step 605 is similar to that described in step 107 of the method 100 with reference to FIG. 10. Details thereof are omitted for the sake of brevity. By completing step 107, isolation units 51 are thereby obtained, each of which includes one of the annealed isolation protection elements 51A′, and a corresponding one of the isolation elements 51B. The doped stack coverings 42A (see FIG. 27) of the stack coverings 42 are also subjected to the annealing process, and are hereinafter denoted by the numeral 42A′ (see FIG. 28). It is noted that the isolation protection elements 51A and the doped stack covering 42A shown in FIG. 30 are subjected to the ion implantation process and thus have the same shading, and that the isolation protection elements 51A and the doped stack coverings 42A include different materials. Similarly, the annealed isolation protection elements 51A′ and the annealed doped stack coverings 42A′ shown in FIG. 31 have the same shading but include different materials. In some embodiments, each of the doped stack coverings 42A and the isolation protection elements 51A′ may include silicon nitride, silicon carbonitride, silicon oxycarbide, silicon oxycarbonitride, silicon carbide, or combinations thereof. In some embodiments, the annealed doped stack coverings 42A′ includes silicon carbonitride, silicon oxycarbide, or silicon oxycarbonitride. In some embodiments, the doped stack covering 42A or the annealed doped stack covering 42A′ include carbon-doped nitride-containing dielectric material (e.g., silicon carbonitride) while the isolation protection elements 51A or the annealed isolation protection elements 51A′ include carbon-doped oxide-containing dielectric material (e.g., silicon oxycarbide).

Referring to FIG. 26 and the example illustrated in FIG. 32, the method 600 proceeds to step 606, where a dummy dielectric 61, a dummy gate 62, a polish-stop layer 63 and a hard mask layer 64 are formed over the stack coverings 42, the stacks 20 and the isolation units 51.

Step 606 is similar to step 109 of the method 100 with reference to FIG. 12, and details thereof are omitted for the sake of brevity. It is noted that in step 606, the dummy dielectric 61 is formed in contact with top surfaces of the stacks 20 through the stack coverings 42.

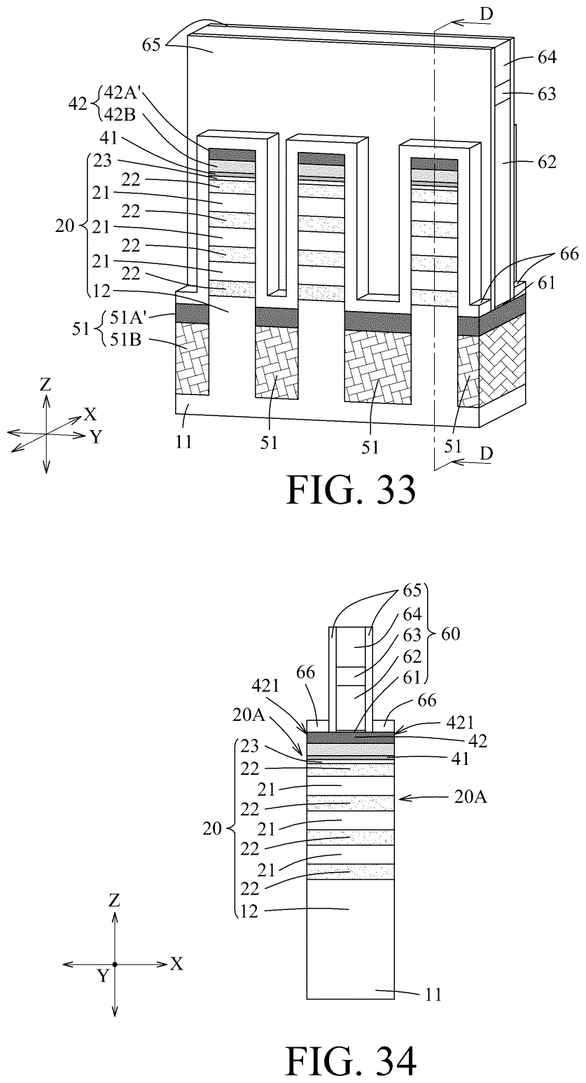

Referring to FIG. 26 and the examples illustrated in FIGS. 33 and 34, the method 600 proceeds to step 607, where a pair of gate spacers 65 is formed at opposite sides of a stack including the dummy dielectric 61, the dummy gate 62, the polish-stop layer 63, and the hard mask layer 64 along the X direction, thereby obtaining a gate structure 60. FIG. 34 is a cross-sectional view of line D-D shown in FIG. 33 in accordance with some embodiments.

By completing step 607, the pair of the gate spacers 65 is formed across the stacks 20, the stack coverings 42 and the isolation units 51 to sandwich the dummy dielectric 61, the dummy gate 62, the polish-stop layer 63, and the hard mask layer 64. Each of the stacks 20 has two portions 20A that are opposite to each other, and that are located at two opposite sides of the gate structure 60 along the X direction. Each of the stack coverings 42 also has two regions 421 that are opposite to each other, and that respectively cover the two portions 20A of a corresponding one of the stacks 20. In addition, a pair of the fin sidewalls 66 are formed at opposite sides of the gate structure 60. The fin sidewalls 66 are conformally formed along the two portions 20A of the stacks 20, the stack coverings 42 and the isolation units 51.

Other details of step 607 are similar to those described in step 110 of the method 100 with reference to FIGS. 13 and 14, and are thus omitted for the sake of brevity.

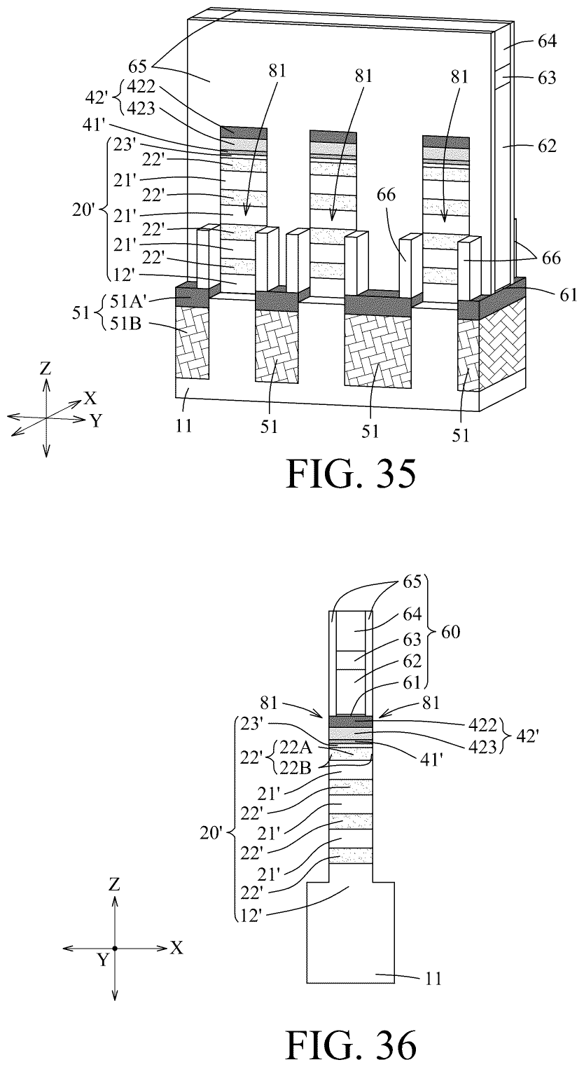

Referring to FIG. 26 and the examples illustrated in FIGS. 35 and 36, the method 600 proceeds to step 608, where the two portions 20A of each of the stacks 20 and the two regions 421 are removed to from source/drain recesses 81. FIGS. 35 and 36 illustrate structures respectively subsequent to the structures shown in FIGS. 33 and 34.

Step 608 is similar to step 111 of the method 100 with reference to FIGS. 15 and 16, and details thereof are omitted for the sake of brevity. By completing step 608, the stack coverings 42, the stress releasing layers 41, the covering layers 23, the second nanosheet layers 22 and the first nanosheet layers 21 (see FIGS. 33 and 34) are respectively formed into patterned stack coverings 42′ (in which, the doped stack coverings are denoted as 422, and the undoped stack coverings are denoted as 423), patterned stress releasing layers 41′, patterned covering layers 23′, second nanosheets 22′ and first nanosheets 21′. In addition, the stacks 20 shown in FIGS. 33 and 34 are formed into patterned stacks 20′.

As shown in FIG. 36, sidewalls of each of the patterned stack coverings 42′, the patterned stress releasing layers 41′, the patterned covering layers 23′, the second nanosheets 22′ and the first nanosheets 21′ may be flush with each other. Each of the second nanosheets 22′ has a main part 22A disposed below the dummy gate 62, and two end regions 22B disposed at two opposite sides of the main part 22A and below the gate spacers 65. In addition, for each of the patterned stacks 20′, a top portion of each of the mesa regions may also be recessed, and the recessed mesa regions are denoted by the numeral 12′.

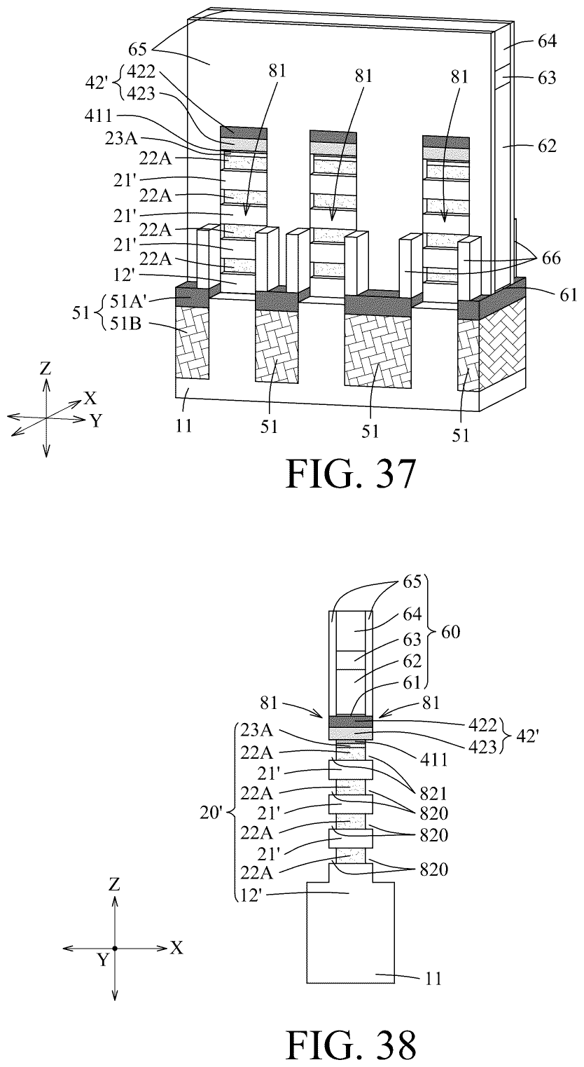

Referring to FIG. 26 and the examples illustrated in FIGS. 37 and 38, the method 600 proceeds to step 609, where the two end regions 22B of each of the second nanosheets 22′ (see FIG. 36) are removed to form multiple pairs of lateral recesses 820, 821 in each of the patterned stacks 20′, remaining the main parts 22A. FIGS. 37 and 38 illustrate structures respectively subsequent to the structures shown in FIGS. 35 and 36.

Step 609 is similar to step 112 of the method 100 with reference to FIGS. 17 and 18, and details thereof are omitted for the sake of brevity. During recessing the second nanosheets 22′, the first nanosheets 21′ and the patterned covering layers 23′ (made of the same material as the first nanosheets 21′) (see FIG. 36) are also slightly recessed. In details, during recessing of the topmost second nanosheets 22′ (see FIG. 36), the presence of the patterned covering layers 23′ permits, in each of the patterned stacks 20′, an etching profile of the topmost second nanosheet 22′ to align with etching profiles of the lower second nanosheets 22′. In certain embodiments, the stress releasing layers 41′ (see FIG. 36) are also laterally recessed in step 609. As such, a pair of the topmost lateral recesses 821 (see FIG. 38) may each have a dimension (measured along the Z direction) larger than a dimension of each of the lower lateral recesses 820 (measured along the Z direction). The recessed stress releasing layers are each denoted by the numeral 411, the recessed covering layers are each denoted by the numeral 23A. In some embodiments, as shown in FIG. 38, the recessed stress releasing layer 411, the recessed covering layer 23A and the topmost main part 22A may have sidewalls thereof flush with each other.

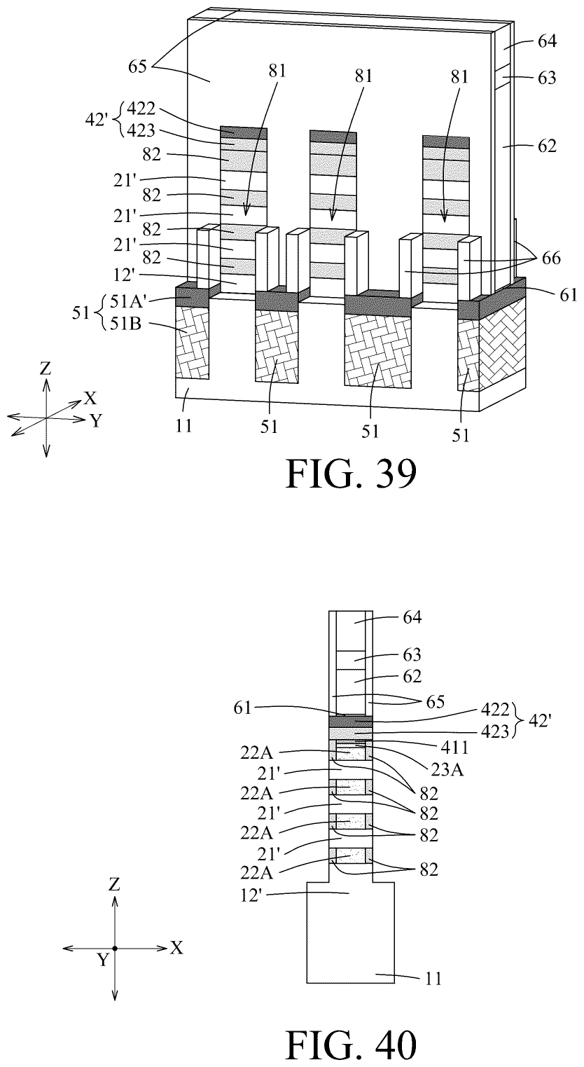

Referring to FIG. 26 and the examples illustrated in FIGS. 39 and 40, the method 600 proceeds to step 610, where multiple pairs of inner spacers 82 are formed respectively in the multiple pairs of the lateral recesses 820, 821. FIGS. 39 and 40 illustrate structures respectively subsequent to the structures shown in FIGS. 37 and 38.

Step 610 is similar to step 113 of the method 100 with reference to FIGS. 19 and 20, and details thereof are omitted for the sake of brevity. As shown in FIGS. 39 and 40, the topmost pairs of the inner spacers 82 (one of which is shown) have a dimension (e.g., measured along the Z direction) larger than a dimension of other lower pairs of the inner spacers 82. In addition, the topmost pairs of the inner spacers 82 are respectively in direct contact with the patterned stack coverings 42′.

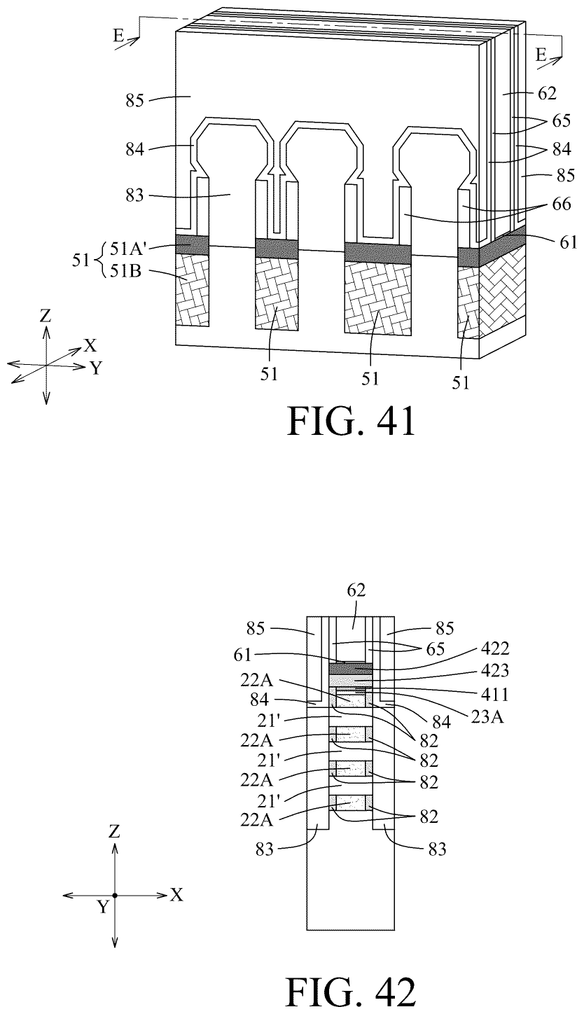

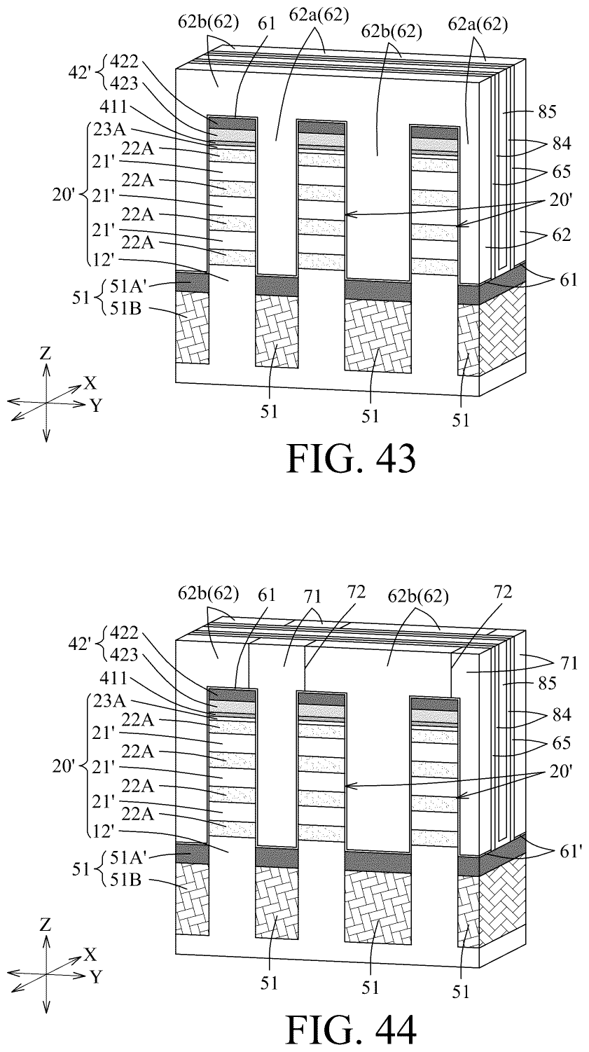

Referring to FIG. 26 and the examples illustrated in FIGS. 41, 42 and 43, the method 600 proceeds to step 611, where source/drain portions 83 are respectively formed in the source/drain recesses 81 (see FIGS. 39 and 40). FIGS. 41 and 42 illustrate structures respectively subsequent to the structures shown in FIGS. 39 and 40. FIG. 43 is a cross-sectional view along the line E-E shown in FIG. 41. In addition, CESL 84 and the ILD 85 are also formed in step 611. Step 611 is similar to step 114 of the method 100 with reference to FIGS. 21 to 23, and details thereof are omitted for the sake of brevity.

Referring to FIG. 26 and the examples illustrated in FIG. 44, the method 600 proceeds to step 612, where first portions 62a (see FIG. 43) of the dummy gate 62 are removed and replaced by wall features 71 (see FIG. 44).

The first portions 62a, each of which is a portion of the dummy gate 62 and each of which is located between two selected adjacent ones of the patterned stacks 20′. Please note that number and/or position of the wall feature(s) 71 may be determined according to practical needs and/or product designs. In some embodiments, step 612 includes: removing first portions 62a, using any suitable processes (e.g., dry or wet etching, but is not limited thereto) to form wall recesses 72; depositing a wall material layer (which is to form the wall features 71) over the structure and fill the wall recesses 72; and removing any excess amount of the wall material layer using any suitable processes (e.g., CMP, but is not limited thereto), so as to obtain the structure shown in FIG. 42. In some embodiments, the wall material layer includes a dielectric material, such as silicon nitride, silicon carbonitride, silicon oxycarbide, silicon oxycarbonitride, but is not limited thereto. Other suitable materials and/or processes for forming the wall features 71 are within the contemplated scope of the present disclosure. By completing step 612, the wall features 71 are formed, each of which is located between the two selected adjacent ones of the patterned stacks 20′ (for the right one of the wall features 71 shown in FIG. 44, only one of the adjacent patterned stacks 20′ is shown). In addition, each of the wall features 71 is also located between two selected adjacent ones of the patterned stack coverings 42′.

Referring to FIG. 26 and the example illustrated in FIG. 45, the method 600 proceeds to step 613, where second portions 62b (see FIG. 44) of the dummy gate 62, and dummy dielectric 61 underneath the second portions 62b, and the main parts 22A are sequentially removed, and a sheet trimming process is performed to form the first nanosheets 21′ into channel nanosheets 21A. After removing the main parts 22A, the remaining patterned stacks are known as nanosheet stacks 20″.

After removing the second portions 62b of the dummy gate 62, first portions of the dummy dielectric 61 that are originally covered by the second portions 62b are exposed and removed, while second portions of the dummy dielectric 61 that are covered by the wall features 71 remain intact. The second portions of the dummy dielectric are known as the patterned dummy dielectric 61′. Other details of step 612 (i.e., the removing process, and the sheet trimming process) are similar to those described in step 115 with reference to FIG. 24, and thus are omitted for the sake of brevity. By completing step 612, for each of the channel nanosheets 21A and the patterned stack coverings 42′, at least a portion thereof is covered by a corresponding one of the patterned dummy dielectric 61′, and thus is connected to an adjacent one of the wall features 71, and a remaining portion of each of the channel nanosheets 21A is exposed from the patterned dummy dielectric 61′.

Referring to FIG. 26 and the example illustrated in FIG. 46, the method 600 proceeds to step 614, where interfacial layers 91, a gate dielectric 92, and a gate electrode 93 are formed.

Step 614 may include: forming the interfacial layers 91 around the exposed portions of the channel nanosheets 21A (that are exposed from the patterned dummy dielectric 61′); then forming the gate dielectric 92 on the interfacial layers 91 around the exposed portions of the channel nanosheets 21A and over the structure shown in FIG. 45; and then forming the gate electrode 93 on the gate dielectric 92, and around the channel nanosheets 21A.

By completing step 614, a gate unit is formed around the channel nanosheets 21A of each of the nanosheet stacks 20″. For each of the channel nanosheets 21A, a portion thereof is connected to a corresponding wall feature 71, and a remaining portion thereof is connected to the gate electrode 93 through a corresponding one of the interfacial layers 91 and a corresponding portion of the gate dielectric 92. For each of the patterned stack coverings 42′, a portion thereof is connected to a corresponding wall feature 71 through a corresponding portion of the patterned dummy dielectric 61′, and a remaining portion thereof is connected to the gate electrode 93 through a corresponding portion of the gate dielectric 92.

Other details of forming the interfacial layers 91, the gate dielectric 92, and the gate electrode 93 are similar to those described in step 116 with reference to FIG. 25, and are thus omitted for the sake of brevity.

Referring to FIG. 26 and the example illustrated in FIG. 47, the method proceeds to step 615, where a planarization process is performed to remove any parts of the elements that are located above top surfaces of the patterned stack coverings 42′.

In some embodiments, the planarization process may be a chemical mechanical planarization (CMP) process, but is not limited thereto. This step is aimed to remove an excess amount of the gate electrode 93, which is located above the top surfaces of the patterned stack coverings 42′. Such excess amount might undesirably increase parasitic capacitance of resultant nanosheet transistors, resulting in performance loss of the resultant nanosheet transistors. In other words, with the removal of such excess amount, nanosheet transistors 701 obtained in step 615 may have relatively low parasitic capacitance and better device performance. After the CMP process, in some embodiments, the wall features 71 may each have a width along the Y direction ranging from about 5 nm to about 100 nm, and a height along the Z direction ranging from about 10 nm to about 200 nm.

In certain embodiments, referring to FIG. 48, the planarization process is performed to further remove elements that are located above top surfaces of the undoped stack coverings 423, so as to further reduce parasitic capacitance of the resultant nanosheet transistors 701.

By completing step 613, the semiconductor structure 700 or 700A (see FIGS. 47 or 48) is obtained, and includes three nanosheet transistors 701 but are not limited thereto. The nanosheet transistors 701 are similar to the nanosheet transistors 301 shown in FIG. 25, except that the nanosheet transistors 701 each further includes one of the patterned stack coverings 42′ (or one of the undoped stack coverings 423) that is disposed above and spaced apart from the channel nanosheets 21A in the Z direction. In addition, the nanosheet transistors 701 shown in FIGS. 47 and 48 are forksheet type of nanosheet transistors, and thus are also different from the GAA type of the nanosheet transistors 301 described with reference to FIG. 25 where the wall features 71 shown in FIGS. 47 and 48 are absent in FIG. 25. Please note that number, and type of the nanosheet transistors 701 may be varied according to practical needs, and product design. In addition, the semiconductor structure 700 also further includes the isolation units 51 that are similar to those described in the semiconductor structure 300 shown in FIG. 25, except that the isolation units 51 of the semiconductor structure 700 are not surrounded by elements similar to the protection film part 351 as found in the semiconductor structure 300.

Both the method 100 and the method 600 include an ion implantation process (step 106, or step 604) which results in formation of the isolation protection elements 51A′ (or known as the upper portions of the isolated units 51), so as to protect the silicon oxide isolation elements 51B (or known as the lower portions of the isolated units 51) in subsequent processing steps. In addition, in both of the methods 100, 600, prior to the ion implantation process, stack coverings (respectively denoted by the numeral 36 in the method 100 with reference to FIG. 6, and the numeral 42 in the method 600 with reference to FIG. 28) are formed to prevent the stacks 20 from being affected by the ion implantation process.

In method 100, the stack coverings 36 are removed after the ion implantation process, so as to obtain the resultant semiconductor structure 300 (see FIG. 25) that is without the stack coverings 36. The stack coverings 36 includes the thin silicon carbonitride protection caps 35a (formed from the protection film 35) and the silicon nitride patterning masks 31 which are comparatively easier to be removed in comparison with the relatively thick silicon carbonitride stack coverings 42 formed in the method 600. After removing the stack coverings 36, remaining portions of the protection film 35, each known as the protection film part 351, remains in the resultant semiconductor structure 300 and is located among each of the isolation units 51 and two adjacent ones of the mesa regions 12′. The protection film 35 is not formed in the method 600.

In method 600, the stack coverings 42 are partially retained as the patterned stack covering 42′ (see FIGS. 47 and 48), and are located above the channel nanosheets 21A. The relatively thick silicon carbonitride stack coverings 42 (or 42′) may serve other functions in addition to protecting the stacks 20 during the ion implantation process. One may freely decide which one of the methods 100, 600 to be used according to practical needs and/or product design.

Please note that each of the method 100 and the method 600 may be used to form the desired type of nanosheet transistors. In the above description, the semiconductor structure 300 formed using the method 100 includes the gate-all-around (GAA) type of nanosheet transistors, and the semiconductor structure 700 formed using the method 600 includes the forksheet type of nanosheet transistors, but are not limited thereto. For instance, in some embodiments, forksheet type of nanosheet transistors may also be prepared using by replacing steps 115 and 116 (of the method 100) with steps 612 to 614 (of the method 600). In other embodiments, GAA type of nanosheet transistors may also be prepared by replacing steps 612 to 614 (of the method 600) with steps 115 and 116 (of the method 100).

The embodiments of the present disclosure have the following advantageous features. By including the ion implantation process in the formation of the isolation units 51, the silicon oxide isolation protection elements 51A′ are doped with silicon and/or carbon dopants, so that the doped silicon oxide isolation protection elements 51A′ have a high resistivity to oxide etching etchants, and the silicon oxide isolation elements 51B can be protected from subsequent oxide etching processes performed during manufacturing process of the semiconductor structure. Since the manufacturing process involves formation of the stacks 20 for forming the channel nanosheets 21A, prior to the ion implantation process, the stack coverings (denoted by the numeral 36, and are formed using the method 100, or denoted by the numeral 42 and are formed using the method 600) are formed to protect the stacks 20 from being affected by the ion implantation process. The present disclosure provides different embodiments to respectively illustrate two process flows, in which the stack coverings are removed in the first process flow (e.g., the method 100 illustrated in FIGS. 1 to 25), and the stack coverings remain in the second process flow (e.g., the method 600 illustrated in FIGS. 26 to 48).

In accordance with some embodiments of the present disclosure, a method for manufacturing a semiconductor structure includes: forming stacks each including a first nanosheet layer and a second nanosheet layer that alternate with each other; forming isolation features each of which is disposed between two adjacent ones of the stacks; performing an ion implantation process such that top portions of the isolation features are formed into isolation protection elements; forming a gate structure over the stacks and the isolation protection elements, each of the stacks having two portions that are opposite to each other and that are located at two opposite sides of the gate structure; removing the two portions of each of the stacks to form source/drain recesses such that the first nanosheet layer is formed into a first nanosheet, the second nanosheet layer is formed into a second nanosheet, and the stacks are formed into patterned stacks; forming source/drain portions respectively in the source/drain recesses; removing a dummy gate of the gate structure after forming the source/drain portions; removing the second nanosheet of each of the patterned stacks; and after removing the second nanosheet of each of the patterned stacks and the dummy gate, forming a gate electrode around the first nanosheet of each of the patterned stacks.

In accordance with some embodiments of the present disclosure, in the ion implantation process, one of silicon, carbon, and a combination thereof, is doped into the top portions of the isolation features.

In accordance with some embodiments of the present disclosure, the ion implantation process is performed by sequentially doping silicon and carbon into the top portions of the isolation features.

In accordance with some embodiments of the present disclosure, the method further includes, prior to performing the ion implantation process, forming stack coverings on the stacks, respectively.

In accordance with some embodiments of the present disclosure, the gate structure is formed over the stack coverings; two regions of each of the stack coverings are removed during removing the two portions of each of the stacks such that the stack coverings are formed into patterned stack coverings; and the gate electrode is formed to be connected to the patterned stack coverings.

In accordance with some embodiments of the present disclosure, the method further includes a planarization process to remove a portion of the gate electrode located above the patterned stack coverings.

In accordance with some embodiments of the present disclosure, the stack coverings and the stacks are formed by: forming a stack protection material layer on a starting material stack including a first nanosheet material layer and a second nanosheet material layer; and patterning the stack protection material layer into the stack coverings and patterning the starting material stack into the stacks.

In accordance with some embodiments of the present disclosure, the patterned stack coverings includes one of silicon nitride, silicon carbonitride, silicon oxycarbide, silicon oxycarbonitride, and combinations thereof.

In accordance with some embodiments of the present disclosure, the method further includes, after the ion implantation process, removing the stack coverings.

In accordance with some embodiments of the present disclosure, the stack coverings and the stacks are formed by: forming patterning masks on a starting material stack including a first nanosheet material layer and a second nanosheet material layer; patterning the starting material stack into the stacks through the patterning masks; and forming protection caps respectively over the patterning masks, thereby obtaining the stack coverings each including one of the patterning masks and a corresponding one of the protection caps.

In accordance with some embodiments of the present disclosure, each of the stacks further includes a mesa region beneath the first nanosheet layer and the second nanosheet layer; the starting material stack further includes a substrate material layer beneath the first nanosheet material layer and the second nanosheet material layer; in the patterning of the starting material stack, the substrate material layer is patterned to form the mesa region of each of the stacks and a base, the stacks being located on the base; the stack coverings and the stacks are formed prior to formation of the isolation features; and in formation of the protection caps, protection liners are simultaneously formed, each of the protection liners being disposed on the base and between two adjacent ones of the stacks to interconnect two adjacent ones of the protection caps, such that after formation of the isolation features, the isolation features are respectively disposed on the protection liners.

In accordance with some embodiments of the present disclosure, after the ion implantation process, each of the stack coverings includes one of silicon nitride, silicon carbonitride, silicon oxycarbide, silicon oxycarbonitride, silicon carbide, and combinations thereof.

In accordance with some embodiments of the present disclosure, the method further includes, after the ion implantation process, removing parts of the protection liners which are located above the isolation features.

In accordance with some embodiments of the present disclosure, a method for manufacturing a semiconductor structure includes: forming stacks each including first nanosheet layers and second nanosheet layers that alternate with the first nanosheet layers; forming isolation units each located between two adjacent ones of the stacks, each of the isolation units including an upper portion and a lower portion, a carbon content of the upper portion being greater than a carbon content of the lower portion; forming a gate structure over the stacks and the isolation units, each of the stacks having two portions that are opposite to each other and that are located at two opposite sides of the gate structure; removing the two portions of each of the stacks to form source/drain recesses such that the first nanosheet layers are formed into first nanosheets, the second nanosheet layers are formed into second nanosheets and the stacks are formed into patterned stacks; forming source/drain portions respectively in the source/drain recesses; removing a dummy gate of the gate structure after forming the source/drain portions; removing the second nanosheets of each of the patterned stacks; and forming a gate electrode around the first nanosheets of each of the patterned stacks after removing the dummy gate and the second nanosheets of each of the patterned stacks.

In accordance with some embodiments of the present disclosure, each of the second nanosheets has a main part and two end regions disposed at two opposite sides of the main part; removing the second nanosheets of each of the patterned stacks includes removing the two end regions of each of the second nanosheets so as to form multiple pairs of spacer recesses in each of the patterned stacks prior to forming the source/drain portions, and removing the main part of each of the second nanosheets after removing the dummy gate; and the method further includes forming multiple pairs of inner spacers respectively in the multiple pairs of the spacer recesses in each of the patterned stacks prior to forming the source/drain portions.

In accordance with some embodiments of the present disclosure, removing the dummy gate includes: removing a first part of the dummy gate located between two selected adjacent ones of the stacks to form a wall recess; forming a wall feature in the wall recess; and removing a second part of the dummy gate after forming the wall feature.

In accordance with some embodiments of the present disclosure, in each of the patterned stacks, a topmost one of the second nanosheets is disposed on a topmost one of the first nanosheets; the method further includes forming stack coverings on the stacks, respectively prior to forming the isolation units; two regions of each of the stack coverings are removed during removing the two portions of each of the stacks such that the stack coverings are formed into patterned stack coverings; the dummy gate is formed over the stack coverings; and the gate electrode is formed to be connected to the patterned stack coverings.

In accordance with some embodiments of the present disclosure, in each of the patterned stacks, a topmost pair of the inner spacers is formed above a topmost one of the first nanosheets and is in direct contact with a corresponding one of the patterned stack coverings.

In accordance with some embodiments of the present disclosure, a semiconductor structure includes a first nanosheet transistor; a second nanosheet transistor, and an isolation unit disposed between the first nanosheet transistor and the second nanosheet transistor. The isolation unit has an upper portion and a lower portion; a carbon content of the upper portion being greater than a carbon content of the lower portion.

In accordance with some embodiments of the present disclosure, each of the first nanosheet transistor and the second nanosheet transistor has channel nanosheets; patterned stack coverings; and a gate unit. The channel nanosheets are spaced apart from each other. The patterned stack coverings are disposed above and spaced apart from the channel nanosheets. The gate unit is disposed around the channel nanosheets and is in direct contact with the patterned stack coverings.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming stacks each including a first nanosheet layer and a second nanosheet layer that alternate with each other;
forming isolation features each of which is disposed between two adjacent ones of the stacks;
performing an ion implantation process such that top portions of the isolation features are formed into isolation protection elements;
forming a gate structure over the stacks and the isolation protection elements, each of the stacks having two portions that are opposite to each other and that are located at two opposite sides of the gate structure;
removing the two portions of each of the stacks to form source/drain recesses such that the first nanosheet layer is formed into a first nanosheet, the second nanosheet layer is formed into a second nanosheet, and the stacks are formed into patterned stacks;
forming source/drain portions respectively in the source/drain recesses;
removing a dummy gate of the gate structure after forming the source/drain portions;
removing the second nanosheet of each of the patterned stacks; and
after removing the second nanosheet of each of the patterned stacks and the dummy gate, forming a gate electrode around the first nanosheet of each of the patterned stacks.

2. The method according to claim 1, wherein in the ion implantation process, one of silicon, carbon, and a combination thereof, is doped into the top portions of the isolation features.

3. The method according to claim 2, wherein the ion implantation process is performed by sequentially doping silicon and carbon into the top portions of the isolation features.

4. The method according to claim 1, further comprising, prior to performing the ion implantation process, forming stack coverings on the stacks, respectively.

5. The method according to claim 4, wherein:
the gate structure is formed over the stack coverings;
two regions of each of the stack coverings are removed during removing the two portions of each of the stacks such that the stack coverings are formed into patterned stack coverings;
the gate electrode is formed to be connected to the patterned stack coverings.

6. The method according to claim 5, further comprising a planarization process to remove a portion of the gate electrode located above the patterned stack coverings.

7. The method according to claim 5, wherein the stack coverings and the stacks are formed by:
forming a stack protection material layer on a starting material stack including a first nanosheet material layer and a second nanosheet material layer; and
patterning the stack protection material layer into the stack coverings and patterning the starting material stack into the stacks.

8. The method according to claim 7, wherein the patterned stack coverings includes one of silicon nitride, silicon carbonitride, silicon oxycarbide, silicon oxycarbonitride, and combinations thereof.

9. The method according to claim 4, further comprising, after the ion implantation process, removing the stack coverings.

10. The method according to claim 9, wherein the stack coverings and the stacks are formed by:
forming patterning masks on a starting material stack including a first nanosheet material layer and a second nanosheet material layer;
patterning the starting material stack into the stacks through the patterning masks; and
forming protection caps respectively over the patterning masks, thereby obtaining the stack coverings each including one of the patterning masks and a corresponding one of the protection caps.

11. The method according to claim 10, wherein:
each of the stacks further includes a mesa region beneath the first nanosheet layer and the second nanosheet layer;
the starting material stack further includes a substrate material layer beneath the first nanosheet material layer and the second nanosheet material layer;
in the patterning of the starting material stack, the substrate material layer is patterned to form the mesa region of each of the stacks and a base, the stacks being located on the base;
the stack coverings and the stacks are formed prior to formation of the isolation features;
in formation of the protection caps, protection liners are simultaneously formed, each of the protection liners being disposed on the base and between two adjacent ones of the stacks to interconnect two adjacent ones of the protection caps, such that after formation of the isolation features, the isolation features are respectively disposed on the protection liners.

12. The method according to claim 11, wherein after the ion implantation process, each of the stack coverings includes one of silicon nitride, silicon carbonitride, silicon oxycarbide, silicon oxycarbonitride, silicon carbide, and combinations thereof.

13. The method according to claim 11, further comprising, after the ion implantation process, removing parts of the protection liners which are located above the isolation features.

14. A method for manufacturing a semiconductor structure, comprising:
forming stacks each including first nanosheet layers and second nanosheet layers that alternate with the first nanosheet layers;
forming isolation units each located between two adjacent ones of the stacks, each of the isolation units including an upper portion and a lower portion, a carbon content of the upper portion being greater than a carbon content of the lower portion;
forming a gate structure over the stacks and the isolation units, each of the stacks having two portions that are opposite to each other and that are located at two opposite sides of the gate structure;
removing the two portions of each of the stacks to form source/drain recesses such that the first nanosheet layers are formed into first nanosheets, the second nanosheet layers are formed into second nanosheets and the stacks are formed into patterned stacks;
forming source/drain portions respectively in the source/drain recesses;
removing a dummy gate of the gate structure after forming the source/drain portions;
removing the second nanosheets of each of the patterned stacks; and
forming a gate electrode around the first nanosheets of each of the patterned stacks after removing the dummy gate and the second nanosheets of each of the patterned stacks.

15. The method according to claim 14, wherein each of the second nanosheets has a main part and two end regions disposed at two opposite sides of the main part;
wherein removing the second nanosheets of each of the patterned stacks includes
prior to forming the source/drain portions, removing the two end regions of each of the second nanosheets so as to form multiple pairs of spacer recesses in each of the patterned stacks;
removing the main part of each of the second nanosheets after removing the dummy gate; and
wherein the method further comprises, forming multiple pairs of inner spacers respectively in the multiple pairs of the spacer recesses in each of the patterned stacks prior to forming the source/drain portions.

16. The method according to claim 15, wherein removing the dummy gate includes:
removing a first part of the dummy gate located between two selected adjacent ones of the stacks to form a wall recess;
forming a wall feature in the wall recess; and
removing a second part of the dummy gate after forming the wall feature.

17. The method according to claim 15,
wherein in each of the patterned stacks, a topmost one of the second nanosheets is disposed on a topmost one of the first nanosheets,
wherein the method further comprises, prior to forming the isolation units, forming stack coverings on the stacks, respectively,
wherein two regions of each of the stack coverings are removed during removing the two portions of each of the stacks such that the stack coverings are formed into patterned stack coverings,
wherein the dummy gate is formed over the stack coverings, and
wherein the gate electrode is formed to be connected to the patterned stack coverings.

18. The method according to claim 17, wherein in each of the patterned stacks, a topmost pair of the inner spacers is formed above a topmost one of the first nanosheets and is in direct contact with a corresponding one of the patterned stack coverings.

19. A semiconductor structure, comprising:
a first nanosheet transistor;
a second nanosheet transistor;
an isolation unit disposed between the first nanosheet transistor and the second nanosheet transistor, the isolation unit having an upper portion and a lower portion; a carbon content of the upper portion being greater than a carbon content of the lower portion.

20. The semiconductor structure according to claim 19, wherein each of the first nanosheet transistor and the second nanosheet transistor has
channel nanosheets that are spaced apart from each other,
patterned stack coverings disposed above and spaced apart from the channel nanosheets, and
a gate unit disposed around the channel nanosheets and being in direct contact with the patterned stack coverings.
